(19) United States
(12) Patent Application Publication
(10) Pub. No.: US 2024/0222524 A1
(43) Pub. Date: Jul. 4, 2024

(54) TRANSISTOR, METHOD OF MANUFACTURING THE TRANSISTOR, ELECTRONIC DEVICE INCLUDING TRANSISTOR, AND ELECTRONIC APPARATUS INCLUDING THE TRANSISTOR

(71) Applicant: Samsung Electronics Co., Ltd., Suwon-si (KR)

(72) Inventors: Minsu SEOL, Suwon-si (KR); Eunkyu LEE, Suwon-si (KR); Junyoung KWON, Suwon-si (KR); Kyung-Eun BYUN, Suwon-si (KR)

(73) Assignee: Samsung Electronics Co., Ltd., Suwon-si (KR)

(21) Appl. No.: 18/507,905

(22) Filed: Nov. 13, 2023

(30) Foreign Application Priority Data
Jan. 4, 2023 (KR) 10-2023-0001323

(51) Int. Cl. H01L 29/786; H01L 29/06; H01L 29/66; H01L 29/78

(52) U.S. Cl. CPC H01L 29/78696; H01L 29/0603; H01L 29/66795; H01L 29/785

(57) ABSTRACT

Provided are a field effect transistor, a method of manufacturing the field effect transistor, and an electronic device and an electronic apparatus each including the field effect transistor. The field effect transistor includes a channel layer disposed on a substrate, a high-k gate insulating layer disposed on the channel layer, a first composite electrode layer connected to a first side of the channel layer, a second composite electrode layer connected to a second side of the channel layer, and a gate electrode layer disposed on the gate insulating layer. At least one of the first and second composite electrode layers includes a contact resistance reducing layer in contact with the channel layer and a conductive layer in contact with the contact resistance reducing layer. The conductive layer is spaced apart from the channel layer.

### CROSS-REFERENCE TO RELATED APPLICATION

This application is based on and claims priority under 35 U.S.C. § 119 to Korean Patent Application No. 10-2023-0001323, filed on Jan. 4, 2023, in the Korean Intellectual Property Office, the disclosure of which is incorporated by reference herein in its entirety.

### BACKGROUND

### 1. Field

The present disclosure relates to a switching element, and more particularly, to a transistor, a method of manufacturing the transistor, an electronic device including the transistor, and an electronic apparatus including the transistor.

### 2. Description of the Related Art

As semiconductor devices have been miniaturized so as to improve the degree of integration of semiconductor devices, performance limitations due to scaling of three-dimensional (3D) bulk materials have appeared. In order to overcome these limitations, studies have been conducted on the use of two-dimensional (2D) layered materials in the semiconductor devices.

In the case of channels using 2D semiconductor materials, while also achieving a reduction in thickness, the influences of short channel effects are smaller than that of silicon (Si). Therefore, silicon scaling limitations may be overcome.

### SUMMARY

Provided are transistors having a relatively low contact resistance.

Provided are transistors having a high carrier drift velocity.

Provided are transistors capable of limiting and/or preventing heat generation during operation.

Provided are methods of manufacturing the transistor.

Provided are electronic devices including the transistor.

Provided are electronic apparatuses including the transistor.

Provided are electronic apparatuses including the electronic device.

Additional aspects will be set forth in part in the description which follows and, in part. will be apparent from the description, or may be learned by practice of the presented embodiments of the disclosure.

According to at least one embodiment, a transistor may include a substrate; a channel layer on the substrate, the channel layer including a two-dimensional semiconductor; a first composite electrode layer connected to a first side of the channel layer; a second composite electrode layer connected to a second side of the channel layer; a gate electrode layer between the first composite electrode layer and the second composite electrode layer; and a high-k gate dielectric layer between the channel layer and the gate electrode layer, wherein at least one of the first and second composite electrode layers comprises a contact resistance reducing layer in contact with the channel layer, and a conductive layer on the contact resistance reducing layer and spaced apart from the channel layer.

In some embodiments, the contact resistance reducing layer may include silicide.

In some embodiments, the contact resistance reducing layer may include Ge and a metal component.

In some embodiments, the transistor may further include a low-k dielectric layer between the high-k gate dielectric layer and the channel layer. The contact resistance reducing layer and the low-k dielectric layer may share an elemental component.

In some embodiments, the low-k dielectric layer may include an oxide layer including at least one of Si and Ge.

In some embodiments, the conductive layer may include one or more types metal.

In some embodiments, the conductive layer may include at least one of Ti, Ni, Mo, W. Co. Pt, Hf, Ta, Cu, Cr, Yb, Er, or Pd.

In some embodiments, the channel layer may include a semiconductor material having a band gap of 0.1 eV or more.

In some embodiments, the contact resistance reducing layer may include two different types of metal and may include at least one of Si or Ge.

In some embodiments, the transistor may further include an insulating layer protruding in a direction perpendicular to a surface of the substrate and having a first length in a direction parallel to the surface of the substrate, wherein the insulating layer may have two side surfaces and a top surface connecting the two side surfaces to each other, and the channel layer may cover the two side surfaces and the top surface of the insulating layer.

In some embodiments, the channel layer may include a plurality of sub-channel layers sequentially stacked in a direction perpendicular to a surface of the substrate and spaced apart from each other in the perpendicular direction, and the gate dielectric layer and the gate electrode layer may surround each of the plurality of sub-channel layers.

In some embodiments, the transistor may further include a plurality of insulating layers connecting the first composite electrode layer and the second composite electrode layer to each other, the plurality of insulating layers sequentially stacked in a direction perpendicular to a surface of the substrate and spaced apart from each other, wherein the channel layer may have a three-dimensional structure surrounding the plurality of insulating layers, and the gate dielectric layer and the gate electrode layer may surround each of the plurality of insulating layers, on the channel layer.

According to at least one embodiment, a method of manufacturing a field effect transistor may include forming a channel layer on a substrate, forming a first protective layer in contact with a first portion of the channel layer, forming a second protective layer in contact with a second portion of the channel layer, forming first and second conductive layers respectively in contact with the first and second protective layers and spaced apart from the channel layer, forming first and second contact resistance reducing layers from the first and second protective layers, forming a gate dielectric layer on the channel layer, and forming a gate electrode layer on the gate dielectric layer.

In some embodiments, the method may further include forming a third protective layer between the channel layer and the gate dielectric layer. In some embodiments, the first to third protective layers may be formed simultaneously and as one protective layer. In some embodiments, the third protective layer may be formed before the first and second protective layers.

In some embodiments, the forming of the first and second contact resistance reducing layers may include heat treating the first and second conductive layers and the first and second protective layers.

In some embodiments, the method may further include forming a dielectric layer from the third protective layer such that the dielectric layer has a permittivity lower than a permittivity of the gate dielectric layers.

In some embodiments, the forming the dielectric layer having the permittivity lower than the permittivity of the gate dielectric layer may be performed after the contact resistance reducing layer is formed.

In some embodiments, the forming the dielectric layer having the permittivity lower than the permittivity of the gate dielectric layer and the forming of the first and second contact resistance reducing layer may be performed simultaneously.

In some embodiments, the first and second contact resistance reducing layers and the dielectric layer having the permittivity lower than the permittivity of the gate dielectric layer may include a same elemental component.

In some embodiments, the forming the dielectric layer having the permittivity lower than the permittivity of the gate dielectric layer may include heat treating the third protective layer in an oxygenated environment.

In some embodiments, the contact resistance reducing layer may include a metal component and at least one of Si or Ge.

In some embodiments, the method may further include forming an insulating layer protruding in a direction perpendicular to a surface of the substrate and having a first length in a direction parallel to the surface of the substrate, wherein the insulating layer may have two side surfaces and a top surface connecting the two side surfaces to each other, and the channel layer may be formed to cover the two side surfaces and the top surface of the insulating layer.

In some embodiments, the forming of the channel layer may include forming a plurality of sub-channel layers spaced apart from each other in a direction perpendicular to a surface of the substrate, wherein the gate dielectric layer and the gate electrode layer may be formed to surround each of the plurality of sub-channel layers.

In some embodiments, the method may further include forming a plurality of insulating layers connecting a first composite electrode layer, including the first conductive layer and the first contact resistance reducing layer, and a second composite electrode layer, including the second conductive layer and the second contact resistance reducing layer, to each other, the plurality of insulating layers being spaced apart from each other in a direction perpendicular to a surface of the substrate, wherein the channel layer may be formed to surround the plurality of insulating layers, and the gate dielectric layer and the gate electrode layer may be formed to surround each of the plurality of insulating layers, on the channel layer.

According to at least one embodiment, an electronic device may include a switching element, and a data storage connected to the switching element, wherein the switching element includes the transistor according to the embodiment.

According to at least one embodiment, an electronic apparatus may include the transistor according to the embodiment and/or the electronic device according to the embodiment.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a first transistor according to at least one embodiment;

FIG. 2 is a cross-sectional view illustrating a second transistor according to at least one embodiment;

FIG. 3 is a cross-sectional view illustrating a third transistor according to at least one embodiment;

FIG. 4 is a perspective view illustrating a fourth transistor according to at least one embodiment;

FIG. 5 is a perspective view illustrating a fifth transistor according to at least one embodiment;

FIG. 6 is a cross-sectional view taken along direction 6-6′ in FIG. 5;

FIG. 7 is a cross-sectional view taken along direction 7-7′ in FIG. 5;

FIG. 8 is a perspective view illustrating a sixth transistor according to at least one embodiment;

FIG. 9 is a cross-sectional view taken along direction 9-9′ in FIG. 8;

FIG. 10 is a cross-sectional view taken along direction 10-10′ in FIG. 8;

FIG. 11 is a perspective view illustrating a seventh transistor according to at least one embodiment;

FIG. 12 is a cross-sectional view taken along direction 12-12′ in FIG. 11;

FIG. 13 is a cross-sectional view taken along direction 13-13′ in FIG. 11;

FIG. 14 is a perspective view illustrating an eighth transistor according to at least one embodiment;

FIG. 15 is a cross-sectional view taken along direction 15-15′ in FIG. 14;

FIG. 16 is a cross-sectional view taken along direction 16-16′ in FIG. 14;

FIGS. 17 to 20 are cross-sectional views illustrating step-by-step procedures of a method of manufacturing a first transistor, according to at least one embodiment;

FIGS. 21 to 25 are cross-sectional views illustrating step-by-step procedures of a method of manufacturing a second transistor, according to at least one embodiment;

FIGS. 26 to 28 are cross-sectional views illustrating a part of a method of manufacturing a transistor, according to at least one embodiment;

FIGS. 29 to 38 are cross-sectional views illustrating step-by-step procedures of a method of manufacturing a fifth transistor, according to at least one embodiment;

FIG. 39 is a block diagram illustrating an electronic device according to at least one embodiment; and

FIGS. 40 to 43 are block diagrams illustrating electronic apparatuses according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. When the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially.” it will be understood that these values should be construed as including a manufacturing or operational tolerance (e.g., ±10%) around the stated numerical values and/or geometric. When referring to “C to D”, this means C inclusive to D inclusive unless otherwise specified. As used herein, the term “and/or” includes any and all combinations of one or more of the associated listed items. Expressions such as “at least one of,” when preceding a list of elements, modify the entire list of elements and do not modify the individual elements of the list.

Hereinafter, a transistor, a method of manufacturing the transistor, and an electronic device and an electronic apparatus including the transistor manufactured by the method, according to some embodiments, will be described in detail with reference to the accompanying drawings. The thicknesses of layers or regions illustrated in the drawings may be slightly exaggerated for clarity of the specification.

Embodiments described herein are only examples, and various modifications may be made thereto from these embodiments. In addition, the terms “above” or “on” as used herein may include not only those that are directly on in a contact manner, but also those that are above in a non-contact manner. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context. Operations are not necessarily limited to the stated order.

Also, functional terms such as those including “ . . . er/or” and “module” described in the specification mean units that process at least one function or operation, and may be implemented as processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Connecting lines or connecting members illustrated in the drawings are intended to represent exemplary functional relationships and/or physical or logical connections between the various elements. It should be noted that many alternative or additional functional relationships, physical connections or logical connections may be present in a practical device.

The use of all illustrations or illustrative terms in the embodiments is simply to describe the technical ideas in detail, and the scope of the disclosure is not limited by the illustrations or illustrative terms unless limited by the claims.

First, transistors according to some embodiments will be described.

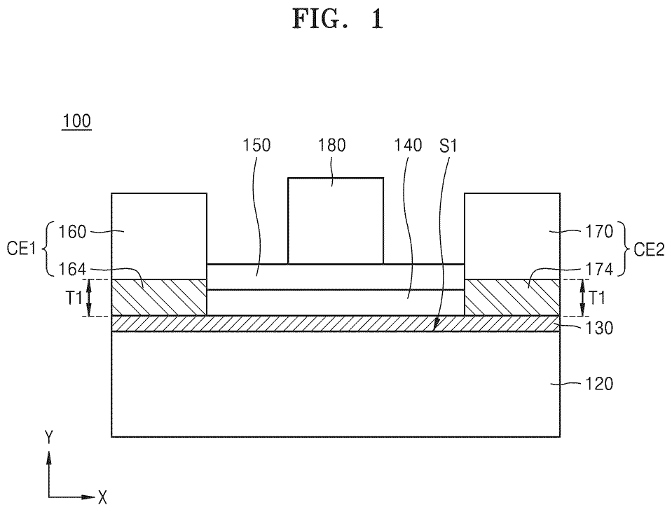

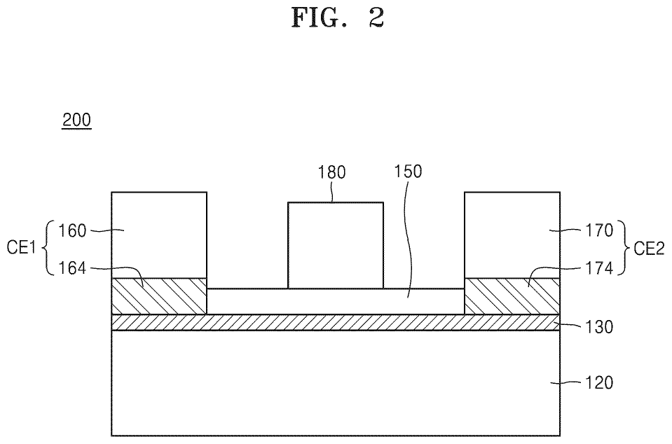

FIG. 1 illustrates a first transistor 100 according to at least one embodiment. The first transistor 100 may be a field effect transistor (FET).

Referring to FIG. 1, the first transistor 100 may include a substrate 120, a channel layer 130, a first electrode layer CE1, a second electrode layer CE2 spaced apart from the first electrode layer CE1, a first dielectric layer 140 and a second dielectric layer 150 sequentially stacked on the channel layer 130, and a gate electrode layer 180 on the second dielectric layer 150, but the examples are not limited thereto.

In some embodiments, the substrate 120 may be a semiconductor layer and/or a substrate including a semiconductor layer. In some embodiments, the substrate 120 may be a compound semiconductor substrate, and may also be a non-compound semiconductor substrate. In some embodiments, the substrate 120 may include an insulating layer alone or in combination with a semiconductor layer or other layers. In some embodiments, the substrate 120 may be a substrate doped with a P-type dopant or an N-type dopant, but the examples are not limited thereto.

The channel layer 130 may be disposed on one surface S1 of the substrate 120, may be in direct contact with the one surface S1 of the substrate 120, and may cover the entire surface S1 of the substrate 120. In some embodiments, the one surface S1 of the substrate 120 may be parallel (and/or substantially parallel) to the X axis and perpendicular (and/or substantially perpendicular) to the Y axis. In some embodiments, the one surface S1 may be parallel to a plane to formed by the X axis and a third orthogonal axis (e.g., a Z-axis, not illustrated). In some embodiments, the one surface S1 of the substrate 120 may be referred to as the top or upper surface of the substrate 120. In some embodiments, the channel layer 130 may be formed to have a uniform (and/or substantially uniform) thickness on the entire one surface S1 of the substrate 120.

In some embodiments, the channel layer 130 may be a two-dimensional (2D) material channel or a channel including a 2D material. For example, the channel layer 130 may be a channel layer including a 2D semiconductor material (hereinafter referred to as a 2D semiconductor channel layer), but the examples are not limited thereto. In some embodiments, the channel layer 130 may be a single layer or a multilayer (in a case where a plurality of 2D semiconductor layers are stacked). For example, the channel layer 130 may include a layer structure in which one to ten 2D semiconductor layers are sequentially stacked. The number of layers is not limited thereto. The number of layers may be ten or more, and/or may be five.

In some embodiments, the 2D semiconductor material may include a semiconductor material having a band gap of 0.1 electron volt (eV) or more. For example, the 2D semiconductor material may include transition metal dichalcogenide (TMD), a TMD-containing material, or black phosphorous (BP), but the examples are not limited thereto. The 2D semiconductor material including the TMD may, for example, include at least one of MoS2, WS2, MoSe2, and/or WSc2, but the examples are not limited thereto.

The first and second electrode layers CE1 and CE2 may be referred to as first and second electrodes, respectively, and may also be variously referred to as, for example, first and second conductive layers, first and second terminals, or first and second terminal layers. One of the first and second electrode layers CE1 and CE2 may be a source electrode (layer), and the other thereof may be a drain electrode (layer). Both the first and second electrode layers CE1 and CE2 may be disposed on the channel layer 130 and may be in electrical and/or direct contact with the channel layer 130. One of the first and second electrode layers CE1 and CE2 may be on one edge of the channel layer 130, and the other thereof may be on the other edge of the channel layer 130. In at least some embodiments, the entire bottom surface of the first electrode layer CE1 may be in direct contact with the channel layer 130. Alternatively, only a portion of the bottom surface of the first electrode layer CE1 may be in contact with the channel layer 130. The entire bottom surface of the second electrode layer CE2 may be in direct contact with the channel layer 130. Alternatively, only a portion of the bottom surface of the second electrode layer CE2 may be in contact with the channel layer 130. The substrate 120, the channel layer 130, and the first electrode layer CE1 may be sequentially stacked in the Y-axis direction. The substrate 120, the channel layer 130, and the second electrode layer CE2 may also be sequentially stacked in the Y-axis direction.

In some embodiments, the first electrode layer CE1 may be a composite electrode layer including at least two types of materials or elements. For example, the first electrode layer CE1 may include a first silicide layer 164 and a first conductive layer 160, which are sequentially provided in a direction perpendicular to the one surface S1 of the substrate 120 (and/or in the Y-axis direction). In some embodiments, the first silicide layer 164 is between the first conductive layer 160 and the channel layer 130 and includes a material layer having a relatively low electrical resistance. For example, the electrical resistance of the first silicide layer 164 may be lower than the electrical resistance of the first conductive layer 160. Accordingly, the drift velocity of carriers (e.g., electrons or holes) through the channel layer 130 in the first transistor 100 may be faster than the drift velocity of carriers in a comparative example where the first conductive layer 160 is in direct contact with the channel layer 130. In addition, because the first silicide layer 164 is provided, the contact resistance between the channel layer 130 and the first electrode layer CE1 may be lowered. Therefore, the amount of heat that may be generated at the interface between the channel layer 130 and the first electrode layer CE1 (e.g., due to resistance) may also be reduced. In this sense, the first silicide layer 164 may also be referred to as a contact resistance reducing layer.

In some embodiments, the thickness T1 of the first silicide layer 164 may be greater than or equal to the thickness of the first dielectric layer 140. In some embodiments, the thickness T1 of the first silicide layer 164 may be less than the thickness of the first conductive layer 160, but the examples are not limited thereto. In some embodiments, the thickness T1 of the first silicide layer 164 may be about 1 nm to about 50 nm, but the examples are not limited thereto.

In some embodiments, the first silicide layer 164 may be (or may include) a metal silicide layer. For example, the metal silicide layer may include a metal and silicon (Si). The metal may include at least one of titanium (Ti), nickel (Ni), molybdenum (Mo), tungsten (W), cobalt (Co), platinum (Pt), hafnium (Hf), tantalum (Ta), copper (Cu), chromium (Cr), ytterbium (Yb), erbium (Er), and/or palladium (Pd), but the examples are not limited thereto.

In some embodiments, the width of the first conductive layer 160 in the horizontal direction (X-axis direction) may be equal to or different from the width of the first silicide layer 164. In some embodiments, the first conductive layer 160 may be or may include a metal layer. In some embodiments, the metal layer may be or include an alloy layer. In some embodiments, the metal layer and/or the alloy layer may each include the same metal as the metal included in the first silicide layer 164.

In FIG. 1, for convenience of illustration and description, the first silicide layer 164 and the first conductive layer 160 are illustrated as two layers that are sequentially formed, and a boundary or interface is illustrated as being present between the two layers. However, in at least some embodiments, no clear boundary line or interface may be present between the first silicide layer 164 and the first conductive layer 160 based on the manufacturing process thereof.

For example, when the first silicide layer 164 and the first conductive layer 160 may represent region of the first electrode layer CE1, which may also be referred to as a single electrode layer including the first silicide region 164 and the first conductive region 160 that are sequentially present.

The layer structure and layer configuration of the second electrode layer CE2 may be the same as and/or substantially similar to the layer structure and layer configuration of the first electrode layer CE1. For example, the second electrode layer CE2 may be a composite electrode layer including at least two types of materials or elements; and the second electrode layer CE2 may include a second silicide layer 174 and a second conductive layer 170, which are sequentially provided in a direction perpendicular to one surface S1 of the substrate 120 (and/or in the Y-axis direction).

In some embodiments, the material, dimensions (e.g., thickness), and role of the second silicide layer 174 may be the same as the material, dimensions, and role of the first silicide layer 164, and the material, dimensions, and role of the second conductive layer 170 may be the same as the material, dimensions, and role of the first conductive layer 160. An arrangement relationship between the second silicide layer 174 and the second conductive layer 170 may be the same as an arrangement relationship between the first silicide layer 164 and the first conductive layer 160. Therefore, the effect due to the presence of the second silicide layer 174 may be the same as the effect due to the presence of the first silicide layer 164.

The first and second silicide layers 164 and 174 are each a compound layer including a metal and silicon (Si) as main components, but other components (elements) may be used instead of silicon among the main components. In some embodiments, the first and second silicide layers 164 and 174 may each be replaced with a compound layer including a metal and germanium (Ge) as main components. For example, the first and second silicide layers 164 and 174 may each include and/or be replaced with a metal germanium compound layer.

In some embodiments, the first and second dielectric layers 140 and 150 may be disposed on the channel layer 130 between the first electrode layer CE1 and the second electrode layer CE2. The first and second dielectric layers 140 and 150 may be in direct contact with the channel layer 130 while covering the entire channel layer 130 between the first electrode layer CE1 and the second electrode layer CE2. The first and second dielectric layers 140 and 150 may be in direct contact with the first and second electrode layers CE1 and CE2. In some embodiments, the first and second dielectric layers 140 and 150 may be in direct contact with the side surfaces of the first and second electrode layers CE1 and CE2. For example, the entire left side surface of the first dielectric layer 140 may be in contact with the side surface of the first silicide layer 164 of the first electrode layer CE1, and the entire right side surface of the first dielectric layer 140 may be in contact with the side surface of the second silicide layer 174 of the second electrode layer CE2. For example, the entire left side surface of the second dielectric layer 150 may be in direct contact with a portion of the side surface of the first silicide layer 164 of the first electrode layer CE1 and a portion of the side surface of the first conductive layer 160 of the first electrode layer CE1. For example, the entire right side surface of the second dielectric layer 150 may be in direct contact with a portion of the side surface of the second silicide layer 174 of the second electrode layer CE2 and a portion of the side surface of the second conductive layer 170 of the second electrode layer CE2.

In some embodiments, the permittivity (dielectric constant) of the first dielectric layer 140 may be different from the permittivity (dielectric constant) of the second dielectric layer 150. For example, the first dielectric layer 140 may be a low-k dielectric layer having a relatively low permittivity, and the second dielectric layer 150 may be a high-k dielectric layer having a relatively high permittivity. Accordingly, in these embodiments, the permittivity of the second dielectric layer 150 may be higher than the permittivity of the first dielectric layer 140.

Because the first dielectric layer 140 that is a low-k dielectric layer is between the second dielectric layer 150 and the channel layer 130, a decrease in channel mobility due to remote phonon scattering may be limited and/or prevented.

In some embodiments, the first dielectric layer 140 may be or may include an oxide layer including an elemental (or main) component (e.g., Si and/or Ge) of the first silicide layer 164 and/or the second silicide layer 174. For example, in some embodiments, the first dielectric layer 140 may be (and/or may include) a silicon oxide layer (SiO₂) and/or, the first dielectric layer 140 may be (and/or may include) an oxide layer including germanium instead of silicon.

In some embodiments, the thickness of the first dielectric layer 140 may be less than the thicknesses T1 of the first silicide layer 164 and the thickness T1 of the second silicide layer 174. In some embodiments, the thickness of the first dielectric layer 140 may be about 0.5 nm to about 2 nm, but the examples are not limited thereto.

In some embodiments, the second dielectric layer 150 may include a high-k material, such as aluminum oxide, hafnium oxide, or titanium oxide, but the examples are not limited thereto.

In some embodiments, the first and second dielectric layers 140 and 150 may, as a whole, act as a gate insulating layer, or only the second dielectric layer 150 may act as a gate insulating layer (as illustrated in FIG. 2).

The gate electrode layer 180 may be disposed on the second dielectric layer 150 and spaced apart from the first and second electrode layers CE1 and CE2. In some embodiments, the material of the gate electrode layer 180 may be the same as and/or substantially similar to the material of the first and second electrode layers CE1 and CE2. For example, the gate electrode layer 180 include at least one of a conductive silicide layer, a metal layer, and/or an alloy layer, but the examples are not limited thereto. The gate electrode layer 180 may also be referred to as a third electrode layer.

The first dielectric layer 140, the second dielectric layer 150, and the gate electrode layer 180 may be sequentially stacked in a direction perpendicular to one surface S1 of the substrate 120 (and/or in the Y-axis direction), and may be collectively referred to as a gate laminate or a gate stack.

FIG. 2 illustrates a second transistor 200 according to at least one embodiment.

Portions different from the first transistor of FIG. 1 will be primarily described below.

Referring to FIG. 2, only the second dielectric layer 150 in the second transistor 200 may be between the channel layer 130 and the gate electrode layer 180. That is, a gate stack on the channel layer 130 may include the sequentially stacked second dielectric layer 150 and gate electrode layer 180, and not the first dielectric layer 140. In at least some of these examples, the second dielectric layer 150 may be in direct contact with the channel layer 130. In some embodiments, the entire left side surface of the second dielectric layer 150 may be in contact with a first silicide layer 164, and the left side surface of the second dielectric layer 150 may be in contact with both the first silicide layer 164 and a first conductive layer 160. In some embodiments, the entire right side surface of the second dielectric layer 150 may be in contact with a second silicide layer 174, and the right side surface of the second dielectric layer 150 may be in contact with both the second silicide layer 174 and a second conductive layer 170. In some embodiments the thickness of the second dielectric layer 150 may be less than, equal to, or greater than the thicknesses T1 of the first silicide layer 164 and/or the thickness T1 of the second silicide layer 174.

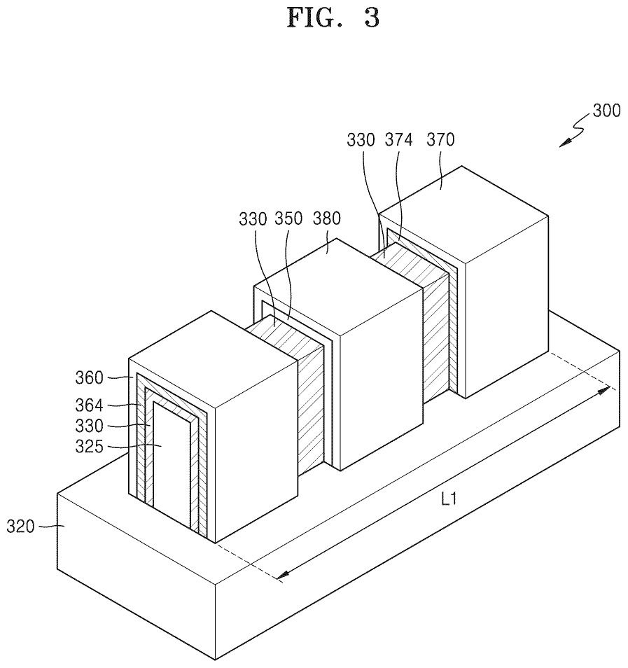

FIG. 3 illustrates a third transistor 300 according to at least one embodiment. The third transistor 300 may be a fin-type FET.

Referring to FIG. 3, an insulating layer 325 may be disposed on a substrate 320. The insulating layer 325 may be a fin type. For example, the insulating layer 325 may be formed in a direction perpendicular to one surface of the substrate 320. The insulating layer 325 may have a first length L1 in a given direction. The material of the substrate 320 may be the same as the material of the substrate 120 of each of the first and/or second transistors 100 and 200. The side surface and the top surface of the insulating layer 325 may be covered with a channel layer 330. The material of the channel layer 330 may be the same as the material of the channel layer 130 described with reference to FIG. 1.

The third transistor 300 includes a first conductive layer 360 and a second conductive layer 370. The material of the first and second conductive layers 360 and 370 may be the same as and/or substantially similar to the material and composition of the first and second conductive layers 160 and 170 of FIG. 1. For example, the first conductive layer 360 and the second conductive layer 370 may each include a metal and/or a metal alloy layer. The transistor 300 includes a gate electrode layer 380. The material of the gate electrode layer 380 may be the same as and/or substantially similar to the material of the gate electrode layer 180 of FIG. 1. A first silicide layer 364 may be between the first conductive layer 360 and the channel layer 330 and may cover a portion of the side surface and the top surface of the channel layer 330, and a second silicide layer 374 may be between the second conductive layer 370 and the channel layer 330 and may cover a portion of the side surface and the top surface of the channel layer 330. The first and second silicide layers 364 and 374 may be material layers that are the same as and/or substantially similar to the first and second silicide layers 164 and 174 of the first transistor 100 of FIG. 1.

A stack including the first silicide layer 364 and the first conductive layer 360, which are sequentially stacked, may be referred to as an electrode layer (e.g., a source electrode layer) and may correspond to the first electrode layer CE1 of FIG. 1. A stack including the second silicide layer 374 and the second conductive layer 370, which are sequentially stacked, may be referred to as an electrode layer (e.g., a drain electrode layer) and correspond to the second electrode layer CE2 of FIG. 1.

The gate insulating layer 350 between the gate electrode layer 380 and the channel layer 330 may extend on the channel layer 330 between the first and second conductive layers 360 and 370 and the gate electrode layer 380. The gate insulating layer 350 may be in direct contact with the channel layer 330. In some embodiments, the material of the gate insulating layer 350 may be the same as and/or substantially similar to the material of the second dielectric layer 150 of FIG. 1.

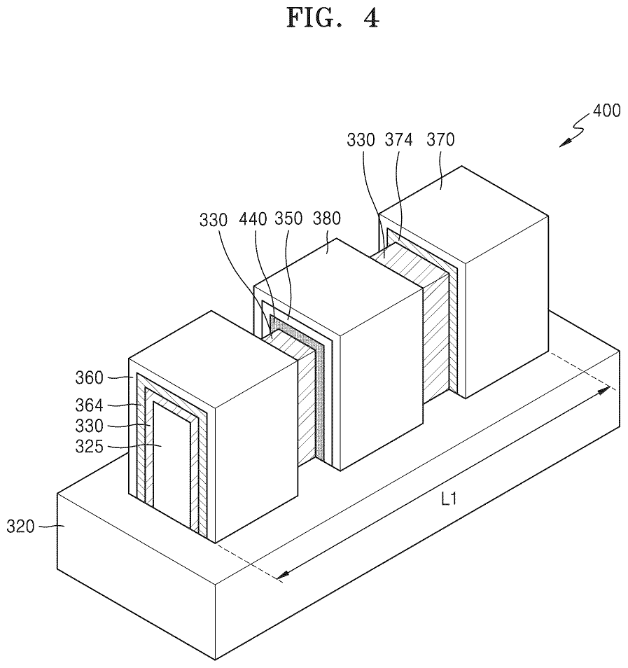

FIG. 4 illustrates a fourth transistor 400 according to at least one embodiment. Like the third transistor 300, the fourth transistor 400 may also be a fin-type FET. Therefore, only portions different from the third transistor 300 will be described.

Referring to FIG. 4, the fourth transistor 400 may further include a third dielectric layer 440 between the gate insulating layer 350 and the channel layer 330. The third dielectric layer 440 is a low-k dielectric layer and may correspond to the first dielectric layer 140 of the first transistor 100 of FIG. 1. Therefore, the effect obtained when the first dielectric layer 140 is provided in the first transistor 100 also appears in the fourth transistor 400. In some embodiments, the material of the third dielectric layer 440 may be the same as and/or substantially similar to the material of the first dielectric layer 140 of the first transistor 100.

In some embodiments, the third dielectric layer 440 and the gate insulating layer 350 on the channel layer 330 may extend up to source and drain electrode layers such that the side surfaces of the third dielectric layer 440 and/or the gate insulating layer 350 contact the side surfaces of the source and/or drain electrode layers.

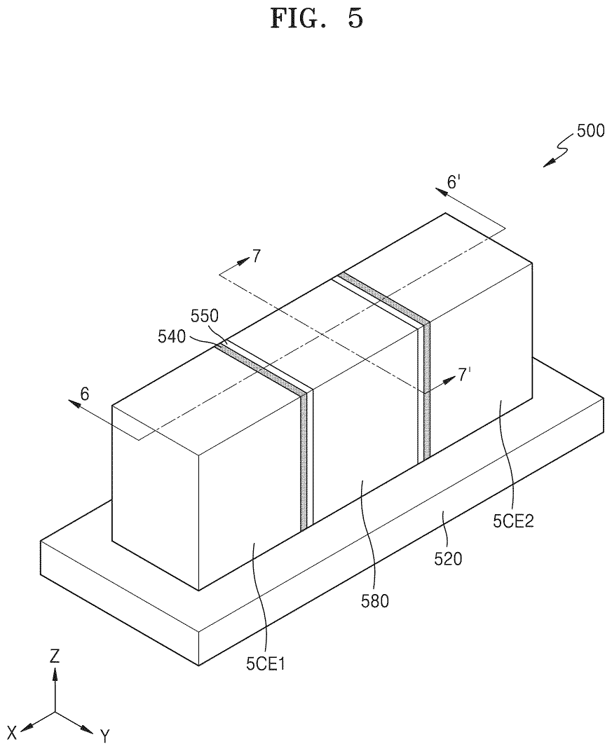

FIG. 5 illustrates a fifth transistor 500 according to at least one embodiment.

Referring to FIG. 5, a first electrode layer 5CE1, a gate electrode layer 580, and a second electrode layer 5CE2 may be sequentially aligned on a substrate 520 in a direction parallel to the X-axis. The material of the substrate 520 may be the same as and/or substantially similar to the substrate 120 of the first transistor 100. For example, the substrate 520 may be an insulating substrate and/or may be a semiconductor substrate on which an insulating layer is formed. An aspect ratio of each of the first electrode layer 5CE1, the gate electrode layer 580, and the second electrode layer 5CE2 may be, respectively greater than or equal to about 1, and/or may be less than about 1. A fourth dielectric layer 540 and a gate insulating layer 550 may be sequentially formed between the first electrode layer 5CE1 and the gate electrode layer 580 in a direction from the first electrode layer 5CE1 to the gate electrode layer 580. The gate insulating layer 550 and the fourth dielectric layer 540 may be sequentially formed between the gate electrode layer 580 and the second electrode layer 5CE2 in a direction from the gate electrode layer 580 to the second electrode layer 5CE2. The material of the gate insulating layer 550 may be the same as and/or substantially similar to the material of the second dielectric layer 150 of FIG. 1 and/or the second dielectric layer 350 of FIGS. 3 and 4. The role of the fourth dielectric layer 540 may be the same as the role of the first dielectric layer 140 of FIG. 1. The material of the fourth dielectric layer 540 may be the same as and/or substantially similar to and/or substantially similar to the material of the first dielectric layer 140 of FIG. 1.

One of the first and second electrode layers 5CE1 and 5CE2 may be a source electrode, and the other thereof may be a drain electrode. The height of each of the first and second electrode layers 5CE1 and 5CE2 in a direction (Z-axis direction) perpendicular to the substrate 520 may be equal to the height of the gate electrode layer 580, but the examples are not limited thereto.

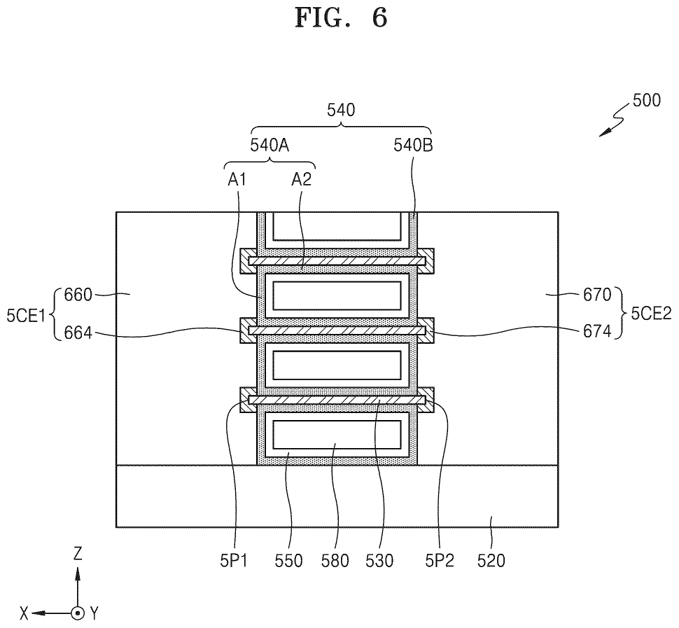

FIG. 6 illustrates a cross-section taken along direction 6-6′ in FIG. 5.

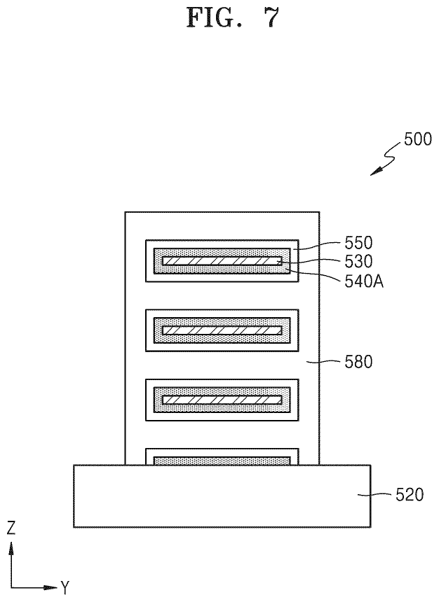

FIG. 7 illustrates a cross-section taken along line 7-7′ in FIG. 5.

The cross-section illustrated in FIG. 6 may be a first cross-section cut from the first electrode layer 5CE1 to the second electrode layer 5CE2 (X-axis direction in FIG. 6) in a direction (Z-axis direction in FIG. 6) perpendicular to the substrate 520. The cross-section illustrated in FIG. 7 may be a second cross-section cut from the first electrode layer 5CE1 to the second electrode layer 5CE2 (Y-axis direction in FIG. 7) in a direction (Z-axis direction in FIG. 7) perpendicular to the substrate 520. Because of manufacturing tolerances, the substrate 520 may not be perfectly flat, and therefore the perpendicular direction may include an approximately perpendicular direction as well as a substantially perpendicular direction. In the present specification, the definitions described above for the first cross-section and the second cross-section are commonly used.

Referring to FIG. 6, the first and second electrode layers 5CE1 and 5CE2 may be disposed on the substrate 520 and spaced apart from each other. A plurality of channel layers 530 may be aligned on the substrate 520 between the first electrode layer 5CE1 and the second electrode layer 5CE2 in a direction (e.g., the Z-axis direction) perpendicular to the top surface of the substrate 520. The channel layers 530 are spaced apart from each other in the perpendicular direction and are not in contact with each other. Although the channel layers 530 are illustrated as including three channel layers, the number of channel layers 530 between the first electrode layer 5CE1 and the second electrode layer 5CE2 may also be less than or may be greater than three. One side of each of the channel layers 530 may be connected to the first electrode layer 5CE1, and the other side of each of the channel layers 530 may be connected to the second electrode layer 5CE2. Accordingly, the channel layers 530 may act as a multi-bridge between the first electrode layer 5CE1 and the second electrode layer 5CE2.

When the entirety of the channel layers 530 is collectively referred to as one channel layer, the respective channel layer of the channel layers 530 may be referred to as a sub-channel layer. In other words, it may be stated that the one channel layer 530 includes a plurality of sub-channel layers.

The first electrode layer 5CE1 may include a plurality of first silicide layers 664 and a first conductive layer 660. The first silicide layers 664 may be aligned side by side in a direction perpendicular to the substrate 520 (e.g., in the Z-axis direction). In at least some embodiments, thought the first silicide layers 664 are spaced apart from each other in the perpendicular direction, the first silicide layers 664 may be connected to each other. The number of first silicide layers 664 may be equal to the number of channel layers 530. Accordingly, the first silicide layers 664 and the channel layers 530 may be provided to correspond to each other one to one. Each of the first silicide layers 664 may surround a protruding portion 5P1 protruding toward the first electrode layer 5CE1 of each of the channel layers 530. For example, all the surfaces of the protruding portion 5P1 may be covered with the first silicide layer 664. For example, the entire protruding portion 5P1 may be completely covered with the first silicide layer 664. Due to this, the protruding portion 5P1 of the channel layer 530 may be spaced apart from the first conductive layer 660. That is, the first silicide layer 664 may be between the first conductive layer 660 and the channel layer 530. Accordingly, carriers moving from the channel layer 530 to the first conductive layer 660 or vice versa pass through the first silicide layer 664.

In some embodiments, the material of the first conductive layer 660 may be the same as and/or substantially similar to the material of the first conductive layer 160 of the first transistor 100 of FIG. 1, and the material of the first silicide layer 664 may be the same as and/or substantially similar to the material of the first silicide layer 164 of the first transistor 100.

The second electrode layer 5CE2 on the right side of the channel layers 530 includes a plurality of second silicide layers 674 and a second conductive layer 670. The number, arrangement, and/or shape of the second silicide layers 674 may be the same as and/or substantially similar to the number, arrangement direction, and shape of the first silicide layers 664.

In addition, the corresponding relationship and corresponding structure between the second silicide layers 674 and the channel layers 530 may also be the same as the corresponding relationship and corresponding structure of the first silicide layers 664 and the channel layers 530. For example, each of the second silicide layers 674 may be in contact with the entire surface of a protruding portion 5P2 protruding toward the right side of each of the channel layers 530, and may cover the entire protruding portion 5P2.

In some embodiments, the material of the second conductive layer 670 may be the same as and/or substantially similar to the material of the second conductive layer 170 of the first transistor 100, and the material of the second silicide layer 674 may be the same as and/or substantially similar to the material of the second silicide layer 174 of the first transistor 100.

Referring to FIGS. 6 and 7 together, a fourth dielectric layer 540, a gate insulating layer 550, and a gate electrode layer 580 may be between the first electrode layer 5CE1 and the second electrode layer 5CE2 and between the channel layers 530.

For example, the fourth dielectric layer 540 may include a first portion 540A having a hollow, closed cross-sectional structure. The hollow, closed cross-sectional structure may include, for example, a closed loop shape including a rectangular, circular, elliptical, or irregular shape. The first portion 540A may include, for example, a sheet portion A1 connected across a gap between the first electrode layer 5CE1 and the second electrode layer 5CE2, and a contact portion A2 in contact with the first electrode layer 5CE1 and the second electrode layer 5CE2. The sheet portion A1 may be referred to as a horizontal portion because the sheet portion A1 is parallel to (or substantially parallel) to the substrate 520. The contact portion A2 may be referred to as a vertical portion because the contact portion A2 is perpendicular to (or substantially perpendicular) to the substrate 520. The first portion 540A may include two sheet portions A1. The contact portion A2 may support the two sheet portions A1 and define a gap between the two sheet portions A1.

A plurality of first portions 540A may be provided, and the first portions 540A may be spaced apart from each other in a direction (Z-axis direction) perpendicular to the substrate 520. For example, the first portions 540A adjacent to each other may be arranged to be separated from each other.

On the other hand, the fourth dielectric layer 540 may include a second portion 540B having an open cross-sectional structure and/or a sheet-type structure at an upper end and/or a lower end thereof. The fourth dielectric layer 540 may be connected between the first electrode layer 5CE1 and the second electrode layer 5CE2. The fourth dielectric layer 540 may be in direct contact with the first electrode layer 5CE1 and the second electrode layer 5CE2. In some embodiments, the fourth dielectric layer 540 may be connected to the first electrode layer 5CE1 and the second electrode layer 5CE2 through other media.

In some embodiments, the distance between the first electrode layer 5CE1 and the second electrode layer 5CE2 may be in a range of 100 nm or less. In some embodiments, the distance between the first electrode layer 5CE1 and the second electrode layer 5CE2 may be in a range of 50 nm or less. In some embodiments, the distance between the first electrode layer 5CE1 and the second electrode layer 5CE2 may be in a range of 20 nm or less.

A gate insulating layer 550 may be provided on the inner surfaces of the first portion 540A and the second portion 540B of the fourth dielectric layer 540. A gate electrode layer 580 may be inside the gate insulating layer 550. The gate insulating layer 550 may be formed to cover the entire inner surfaces of the first and second portions 540A and 540B. The gate insulating layer 550 may be in direct contact with the first and second portions 540A and 540B.

In FIG. 6, the first portion 540A and the gate insulating layer 550 may have a structure that surrounds the entire gate electrode layer 580. Accordingly, the gate electrode layer 580 may correspond to the entire inner surface of the first portion 540A with the gate insulating layer 550 therebetween.

Referring to FIG. 7, the fourth dielectric layer 540 may include a first portion 540A having a hollow, closed cross-section structure. A plurality of first portions 540A may be provided. In this case, the first portions 540A may be spaced apart from each other. The gate insulating layer 550 may be between the first portion 540A and the gate electrode layer 580. The gate electrode layer 580 may be provided around the gate insulating layer 550 and surround the gate insulating layer 550. The first portions 540A may be spaced apart from each other in the height direction of the fifth transistor 500, that is, in a direction (Z-axis direction) perpendicular to the substrate 520, the gate insulating layer 550 may be outside the first portion 540A, and the gate insulating layer 550 and the gate electrode layer 580 may surround the first portion 540A. For example, the gate insulating layer 550 may surround the entire first portion 540A. In addition, the gate electrode layer 580 may surround the entire side of the first portion 540A. Accordingly, the present embodiment may have a so-called all-around gate structure. The first portion 540A in FIG. 6 and the first portion 540A in FIG. 7 may be provided alternately in a direction perpendicular to the substrate 520. A channel layer 530 may be inside the first portion 540A.

The fifth transistor 500 described above is a FET and has a multi-bridge type channel so that a short channel effect may be suppressed and the thickness and length of the channel may be effectively reduced. In addition, because the fifth transistor 500 includes the silicide layers 664 and 674 between the channel layer 530 and the first and second electrode layers 5CE1 and 5CE2, the fifth transistor 500 may exhibit the same effect as described in the first transistor 100. In addition, because the fifth transistor 500 has a subminiature size and excellent electrical performance, the fifth transistor 500 may be suitable for application to an integrated circuit device having a high degree of integration.

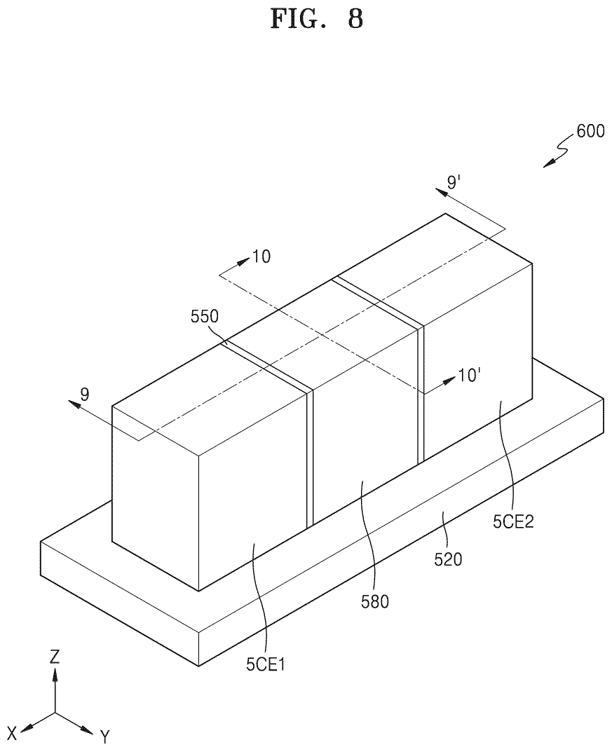

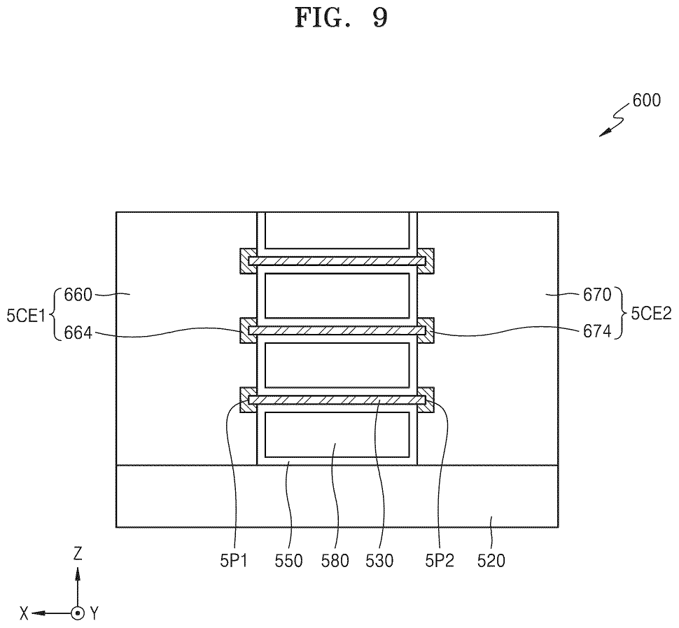

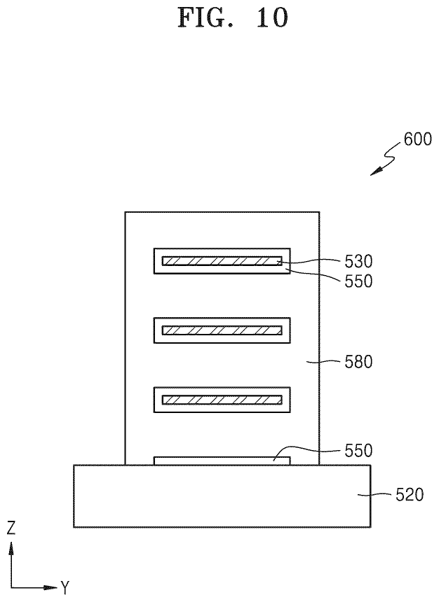

FIGS. 8 to 10 illustrate a sixth transistor 600 according to at least one embodiment. FIG. 9 illustrates a cross-section taken along direction 9-9′ in FIG. 8, and FIG. 10 illustrates a cross-section taken along direction 10-10′ in FIG. 8.

Only portions different from the fifth transistor 500 of FIG. 5 will be described.

Referring to FIGS. 8 to 10 together, the sixth transistor 600 does not include a low-k dielectric layer (e.g., fourth dielectric layer 540) between the channel layer 530 and the gate insulating layer 550. Accordingly, the channel layer 530 may be in direct contact with the gate insulating layer 550. In addition, first and second electrode layers 5CE1 and 5CE2 may be in direct contact with the gate insulating layer 550. That is, the first and second conductive layers 660 and 670 and the first and second silicide layers 664 and 674 around the channel layer 530 may be in direct contact with the gate insulating layer 550 between the channel layers 530.

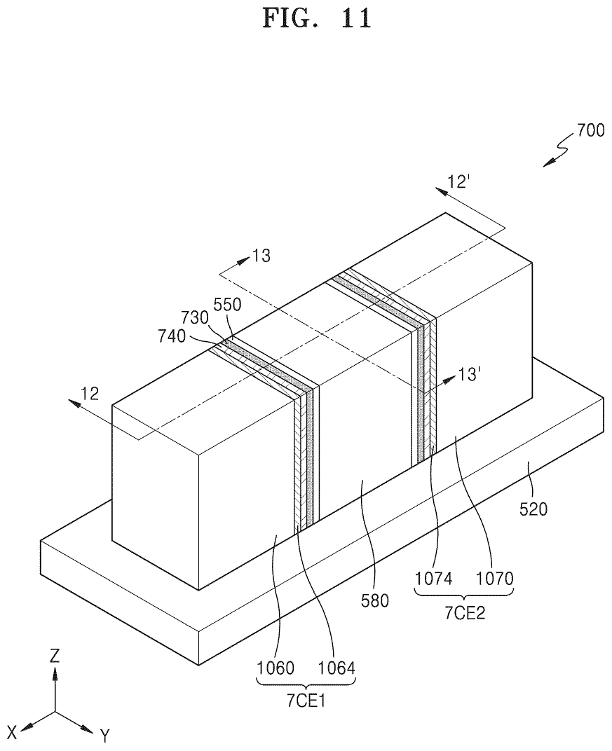

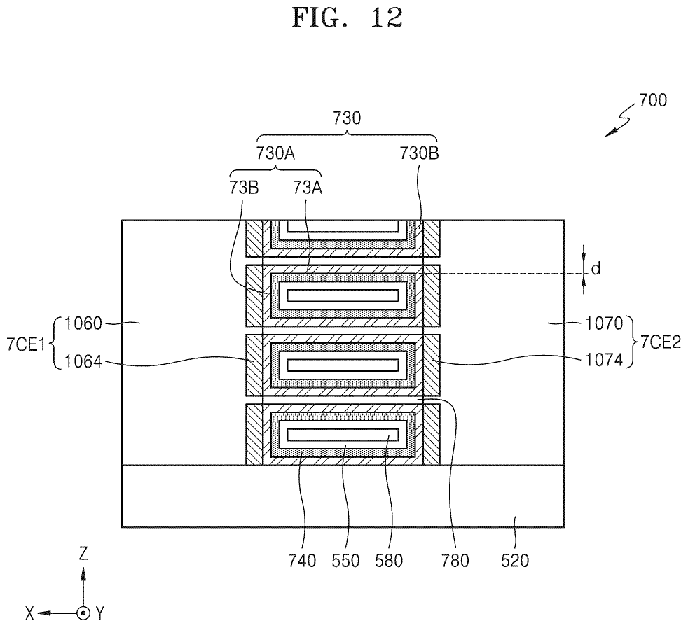

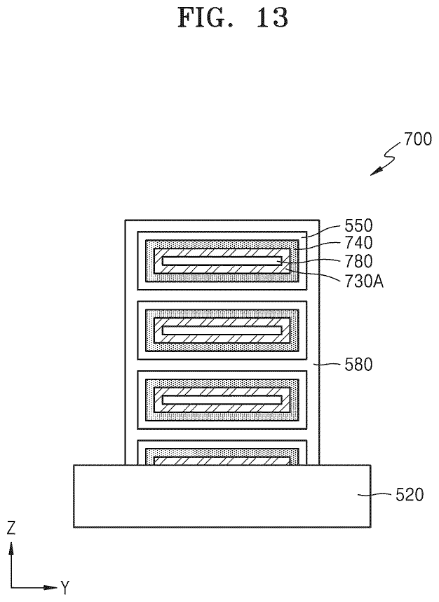

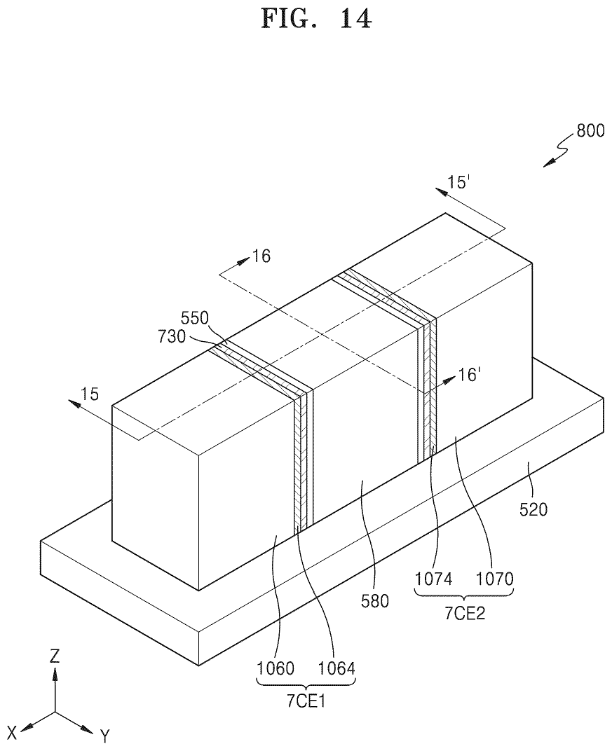

FIG. 11 illustrates a seventh transistor 700 according to at least one embodiment. FIG. 12 illustrates a cross-section taken along direction 12-12′ in FIG. 11; and FIG. 13 illustrates a cross-section taken along direction 13-13′ in FIG. 11. Only portions different from the fifth transistor 500 of FIG. 5 will be discussed.

Referring to FIG. 11, a first electrode layer 7CE1, the gate electrode layer 580, and a second electrode layer 7CE2 may be sequentially aligned on the substrate 520 in a direction parallel to the X-axis. An aspect ratio of each of the first electrode layer 7CE1, the gate electrode layer 580, and the second electrode layer 7CE2 may be, respectively, greater than or equal to about 1, or may be less than about 1. In some embodiments, the gate electrode layer 580 may be a single layer or a multilayer in which a plurality of single layers are stacked.

The channel layer 530, a fifth dielectric layer 740, and the gate insulating layer 550 may be sequentially formed between the first electrode layer 7CE1 and the gate electrode layer 580 in a direction from the first electrode layer 7CE1 to the gate electrode layer 580. The gate insulating layer 550, the fifth dielectric layer 740, and a channel layer 730 may be sequentially formed between the gate electrode layer 580 and the second electrode layer 7CE2 in a direction from the gate electrode layer 580 to the second electrode layer 7CE2.

In some embodiments, the material of the channel layer 730 may be the same as and/or substantially similar to the material of the channel layer 130 of the first transistor 100.

In some embodiments, the fifth dielectric layer 740 is a low-k dielectric, and the material of the fifth dielectric layer 740 may be the same as and/or substantially similar to the material of the first dielectric layer 140 of the first transistor 100.

One of the first and second electrode layers 7CE1 and 7CE2 may be a source electrode, and the other thereof may be a drain electrode. The height of each of the first and second electrode layers 7CE1 and 7CE2 in a direction (Z-axis direction) perpendicular to the substrate 520 may be equal to the height of the gate electrode layer 580, but the examples are not limited thereto.

The cross-section illustrated in FIG. 12 is a first cross-section cut from the first electrode layer 7CE1 to the second electrode layer 7CE2 (X-axis direction in FIG. 12) in a direction (Z-axis direction in FIG. 12) perpendicular to the substrate 520, according to at least one embodiment.

The cross-section illustrated in FIG. 13 is a second cross-section cut from the first electrode layer 7CE1 to the second electrode layer 7CE2 (Y-axis direction in FIG. 13) in a direction (Z-axis direction in FIG. 13) perpendicular to the substrate 520. Because the substrate 520 may not be perfectly flat, the perpendicular direction may include an approximately perpendicular direction as well as a substantially perpendicular direction, according to the at least one embodiment.

Referring to FIG. 12, the channel layer 730 may include a first channel 730A having a hollow, closed cross-section structure. The hollow, closed cross-sectional structure may include, for example, a closed loop shape including a rectangular, circular, elliptical, or irregular shape. The first channel 730A may include, for example, a sheet portion 73A connected across a gap between the first electrode layer 7CE1 and the second electrode layer 7CE2, and a contact portion 73B in contact with the first electrode layer 7CE1 and the second electrode layer 7CE2. The contact portion 73B may be expressed as a spacer or a spacer portion. The sheet portion 73A may be referred to as a horizontal portion because the sheet portion 73A is parallel to or substantially parallel to the substrate 520. The contact portion 73B may be referred to as a vertical portion because the contact portion 73B is perpendicular to or substantially perpendicular to the substrate 520. The first channel 730A may include two sheet portions 73A. The contact portion 73B may support the two sheet portions 73A and define a gap between the two sheet portions 73A.

A plurality of first channels 730A may be provided, and the first channels 730A may be spaced apart from each other in a direction (Z-axis direction) perpendicular to the substrate 520. For example, the first channels 730A adjacent to each other may be arranged to be separated from each other.

The channel layer 730 may include a second channel 730B having an open cross-sectional structure or a sheet-type structure at an upper end and/or a lower end thereof in a first cross-section. The channel layer 730 may connect the first electrode layer 7CE1 and the second electrode layer 7CE2 to each other so as to act as a passage through which current flows between the first electrode layer 7CE1 and the second electrode layer 7CE2.

The first electrode layer 7CE1 may include a first conductive layer 1060 and a plurality of first silicide layers 1064. The first silicide layers 1064 may be arranged side by side in a direction (Z-axis direction) perpendicular to the substrate 520 and spaced apart from each other. Gaps between the first silicide layers 1064 spaced apart from each other may be filled with the first conductive layers 1060. The first conductive layer 1060 may be provided to cover the entire side surfaces of the first silicide layers 1064 opposite to the side surface in direct contact with the channel layer 730 and cover the top surfaces and bottom surfaces of the first silicide layers 1064.

However, in the structure illustrated in FIG. 12, the first conductive layer 1060 may be omitted from the top surface of the first silicide layer 1064, which is the uppermost layer, and the bottom surface of the first silicide layer 1064, which is the lowermost layer, among the first silicide layers 1064. Therefore, in at least one embodiment, the bottom surface of the first silicide layer 1064, which is the lowermost layer, may be in direct contact with the substrate 520, and/or may be formed in a structure that is not in contact with the substrate 520.

The first electrode layer 7CE1 may have a layer structure and layer configuration in which the first silicide layers 1064 are between the first conductive layer 1060 and the channel layer 730 and are in direct contact with the channel layer 730. In such a layer structure, the gap between the first silicide layers 1064 corresponds to the insulating layer 780 between the vertically aligned channel layers 730. For example, the first conductive layer 1060 between the first silicide layers 1064 may be in direct contact with the side surface of the insulating layer 780. The entire side surface of the insulating layer 780 facing the first electrode layer 7CE1 may be in contact with the first conductive layer 1060. The entire side surface of the channel layer 730 facing the first electrode layer 7CE1 may be in direct contact with the first silicide layers 1064.

As a result, the surface (e.g., the side surface) of the stack between the first electrode layer 7CE1 and the second electrode layer 7CE2 (e.g., the stack including the channel layer 730, the insulating layer 780, the fifth dielectric layer 740, the gate insulating layer 550, and the gate electrode layer 580 (hereinafter referred to as ‘channel-gate stack’)), which faces the first electrode layer 7CE1, may be in directly contact with the side surface of the first electrode layer 7CE1 including the first conductive layer 1060 and the first silicide layers 1064. Although the mutual contact between the surface of the channel-gate stack and the side surface of the first electrode layer 7CE1 has been described, a portion of the channel-gate stack (e.g., the insulating layer 780) may be provided in a form connected to the first conductive layer 1060. Therefore, the contact between the surface and the side surface described above may include connection of the two members.

The second electrode layer 7CE2 may include a second conductive layer 1070 and a plurality of second silicide layers 1074. The second electrode layer 7CE2 has a layer structure and layer configuration that may correspond to those of the first electrode layer 7CE1. As seen from FIG. 12, the first and second electrode layers 7CE1 and 7CE2 may face each other with the channel-gate stack therebetween, and may be bilaterally symmetrical with respect to the channel-gate stack. Therefore, the corresponding relationship between the first electrode layer 7CE1 and the channel-gate stack, the arrangement and corresponding relationship between the first conductive layer 1060 and the first silicide layers 1064, the relationship in which the first conductive layer 1060 and the first silicide layers 1064 correspond to the channel-gate stack, and the like may be equally applied to the corresponding relationship between the second electrode layer 7CE2 and the channel-gate stack.

The thicknesses (measured in the Z-axis direction) of the first silicide layers 1064 vertically spaced apart from each other in FIG. 12 may be equal to or substantially equal to each other. However, the thicknesses of some first silicide layers 1064 may be different from the others thereof. For example, the height of the uppermost or lowermost silicide layer among the first silicide layers 1064 may be different from the remainder thereof. In addition, the widths of the first silicide layers 1064 measured in a direction (X-axis direction) parallel to the top surface of the substrate 520 may be equal to (or substantially equal) to each other.

For convenience of description, FIG. 12 illustrates that there is a physical layer boundary between the first conductive layer 1060 and the first silicide layer 1064. However, because the first silicide layer 1064 is formed through diffusion and combination of materials by a heat treatment process, there may not be a physical layer boundary or a physically clear layer boundary between the two layers 1060 and 1064, as illustrated in FIG. 12. In some embodiments, the first silicide layer 1064 may be regarded as a silicide region.

These descriptions may be equally applied to the second conductive layer 1070 and the second silicide layer 1074 of the second electrode layer 7CE2.

In some embodiments, the materials of the first and second conductive layers 1060 and 1070 of the first and second electrode layers 7CE1 and 7CE2, which are composite electrode layers, may be the same as and/or substantially similar to the materials of the first and second conductive layers 160 and 170 of the first transistor 100. In some embodiments, the materials of the first and second silicide layers 1064 and 1074 of the first and second electrode layers 7CE1 and 7CE2 may be the same as and/or substantially similar to the materials of the first and second silicide layers 164 and 174 of the first transistor 100.

On the other hand, because FIG. 12 illustrates a cross-section taken along direction 12-12′ in FIG. 11, it is shown that the channel layer 730, the first silicide layer 1064, and the second silicide layer 1074 are all vertically spaced apart from each other.

However, referring to FIGS. 11 to 13 together, the channel layer 730 has a structure that completely surrounds the insulating layer 780 connecting the first conductive layer 1060 and the second conductive layer 1070 to each other. In addition, the channel layer 730 may cover the entire side surface of the first electrode layer 7CE1 perpendicular to the insulating layer 780 in the +X-axis direction, and may cover the entire side surface of the second electrode layer 7CE2 perpendicular to the insulating layer 780 in the −X-axis direction.

As a result, the channel layer 730 does not exist as a plurality of channels divided or separated between the first electrode layer 7CE1 and the second electrode layer 7CE2, but may be one channel layer that continuously exists over the entire circumferential surfaces of the insulating layers 780 and the entire inner surfaces of the first and second electrode layers 7CE1 and 7CE2 and has a three-dimensional (3D) structure.

Because the first and second silicide layers 1064 and 1074 are also provided to correspond to the channel layer 730, the first and second silicide layers 1064 and 1074 may also be one continuous silicide layer.

Considering these results, it may be stated that the seventh transistor 700, which is a multi-bridge channel FET (MBCFET), has one channel layer having a continuous 3D structure and silicide layers respectively on both sides of the channel layer.

In some embodiments, the channel layer 730 may be connected to the first electrode layer 7CE1 and the second electrode layer 7CE2 through other media.

Referring back to FIG. 12, because the first channel 730A has a hollow, closed cross-sectional structure, the first channel 730A may be in direct contact with the first electrode layer 7CE1 and the second electrode layer 7CE2, and the contact area may be increased by adjusting the thickness of the hollow of the first channel 730A. For example, the contact area between the first channel 730A and the first electrode layer 7CE1 and the contact area between the first channel 730A and the second electrode layer 7CE2 may be adjusted by adjusting the length of the spacer portion 73B of the first channel 730A. For example, the length of the spacer portion 73B may be in a range of 100 nm or less. In some embodiments, the length of the spacer portion 73B may be in a range of 50 nm or less. In some embodiments, the length of the spacer portion 73B may be in a range of 20 nm or less. In some embodiments, the length of the spacer portion 73B may be in a range of 10 nm or less.

In some embodiments, the thickness d of the sheet portion 73A connected between the first electrode layer 7CE1 and the second electrode layer 7CE2 in the first channel 730A may be in a range of 20 nm or less. In some embodiments, the thickness d of the sheet portion 73A of the first channel 730A may be in a range of 10 nm or less. In some embodiments, the thickness d of the sheet portion 73A of the first channel 730A may be in a range of 5 nm or less. In some embodiments, the thickness d of the sheet portion 73A of the first channel 730A may be in a range of 1 nm or less. In some embodiments, the distance between the first electrode layer 7CE1 and the second electrode layer 7CE2 may be in a range of 100 nm or less. In some embodiments, the distance between the first electrode layer 7CE1 and the second electrode layer 7CE2 may be in a range of 50 nm or less. In some embodiments, the distance between the first electrode layer 7CE1 and the second electrode layer 7CE2 may be in a range of 20 nm or less.

A fifth dielectric layer 740 may be provided on the inner surfaces of the first channel 730A and the second channel 730B. The inner surfaces of the first channel 730A and the second channel 730B may include a surface (e.g., an inner surface) opposite to the surface (e.g., an outer surface) of the channel layer 730 in contact with the first and second electrode layers 7CE1 and 7CE2, and a surface (e.g., a top surface or a bottom surface) opposite to the surface (e.g., a bottom surface or a top surface) of the channel layer 730 in contact with the insulating layer 780. In some embodiments, the fifth dielectric layer 740 may be formed along the inner surfaces, may cover the entire inner surfaces, and may be in direct contact with the inner surfaces.

Because the entire structure of the channel layer 730 may have a 3D shape as described above, the fifth dielectric layer 740 formed on the entire inner surface of the channel layer 730 may also have a 3D shape. At this time, the shape of the fifth dielectric layer 740 may be similar to the shape of the channel layer 730.

The gate insulating layer 550 may be provided on the inner surface of the fifth dielectric layer 740. The gate insulating layer 550 may cover the entire inner surface of the fifth dielectric layer 740 and may be in direct contact with the inner surface of the fifth dielectric layer 740. The inner surface of the fifth dielectric layer 740 may include a surface (an inner surface and a bottom surface or a top surface) opposite to the surface (an outer surface and a top surface or a bottom surface) of the fifth dielectric layer 740 in contact with the channel layer 730. Because the gate insulating layer 550 may be provided on the entire inner surface of the fifth dielectric layer 740, the gate insulating layer 550 may also have a 3D structure. The shape of the 3D structure of the gate insulating layer 550 may be similar to the shape of the 3D structure of the fifth dielectric layer 740.

In some embodiments, the gate insulating layer 550 and the fifth dielectric layer 740 may be collectively referred to as a gate insulating layer.

The gate electrode layer 580 may be provided on the inner surface of the gate insulating layer 550. The gate electrode layer 580 may be in contact with the inner surface of the gate insulating layer 550 and cover the entire inner surface of the gate insulating layer 550. The inner surface of the gate insulating layer 550 may include a surface (an inner surface and a bottom surface or a top surface) opposite to the surface (an outer surface and a top surface or a bottom surface) of the gate insulating layer 550 in contact with the fifth dielectric layer 740.

As a result, the gate insulating layer 550, the fifth dielectric layer 740, and the channel layer 730, which may be referred to as being sequentially stacked in a direction from the insulating layer 780 to the gate electrode layer 580, may be provided between the gate electrode layer 580 and the insulating layer 780 in the vertical direction above and below the gate electrode layer 580. The gate insulating layer 550, the fifth dielectric layer 740, and the channel layer 730, which may be referred to as being sequentially stacked from the gate electrode layer 580 to the first and second electrode layers 7CE1 and 7CE2, may be provided between the gate electrode layer 580 and the first and second electrode layers 7CE1 and 7CE2, e.g., in the horizontal direction (direction parallel to the X-axis).

In the first cross-section illustrated in FIG. 12, the first channel 730A, the fifth dielectric layer 740, and the gate insulating layer 550 may be sequentially stacked and may have a layer structure that surrounds the entire gate electrode layer 580. Accordingly, the gate electrode layer 580 may correspond to the entire inner surface of the first channel 730A with the fifth dielectric layer 740 and the gate insulating layer 550 therebetween.

The insulating layers 780 may be between the first channels 730A and between the first channel 730A and the second channel 730B. The insulating layers 780 may be disposed across the gap between the first electrode layer 7CE1 and the second electrode layer 7CE2. The insulating layers 780 may be arranged in a line in a direction perpendicular to the substrate 520 and spaced apart from each other.

The insulating layer 780 may be in contact with the first electrode layer 7CE1 and the second electrode layer 7CE2. For example, the insulating layer 780 may be in direct contact with the first conductive layer 1060 of the first electrode layer 7CE1 and may be in direct contact with the second conductive layer 1070 of the second electrode layer 7CE2.

The insulating layer 780 may also function as a support layer for depositing channels during the manufacturing process. In some embodiments, the insulating layer 780 may have a thickness in a range of 100 nm or less, but the examples are not limited thereto. In some embodiments, the insulating layer 780 may have a thickness in a range of 20 nm or less. In some embodiments, the insulating layer 780 may include at least one of low-doped silicon, SiO₂, Al₂O₃, HfO₂, and/or Si₃N₄, but the examples are not limited thereto.

In the first cross-section illustrated in FIG. 12, the first channel 730A may have a hollow, closed cross-sectional structure, may have a multi-bridge structure between the first electrode layer 7CE1 and the second electrode layer 7CE2, and may be connected to the first electrode layer 7CE1 and the second electrode layer 7CE2. The first electrode layer 7CE1 and the second electrode layer 7CE2 may be disposed on the substrate 520 and spaced apart from each other in a first direction. The first channel 730A may be between the first electrode layer 7CE1 and the second electrode layer 7CE2 and spaced apart from each other in a second direction perpendicular to the substrate 520. The first direction may be an X-axis direction, and the second direction may be a Z-axis direction.

Referring to the second cross-section illustrated in FIG. 13, the channel layer 730 may include the first channel 730A having a hollow, closed cross-sectional structure. A plurality of first channels 730A may be provided. In this case, the first channels 730A may be spaced apart from each other. The fifth dielectric layer 740 and the gate insulating layer 550 may be sequentially stacked between the first channel 730A and the gate electrode layer 580.

Because the low-k fifth dielectric layer 740 is between the first channel 730A and the high-k gate insulating layer 550, remote phonon scattering may also be suppressed or prevented in the seventh transistor 700, like the transistors described above.

Subsequently, as illustrated in FIG. 13, the gate electrode layer 580 may be provided around the gate insulating layer 550 so as to surround the gate insulating layer 550, the fifth dielectric layer 740, the first channel 730A, and the insulating layer 780. In the second cross-section, the first channels 730A may be spaced apart from each other in the height direction of the seventh transistor 700, that is, in a direction (Z-axis direction) perpendicular to the substrate 520, the fifth dielectric layer 740 and the gate insulating layer 550 may be outside the first channel 730A, and the fifth dielectric layer 740, the gate insulating layer 550, and the gate electrode layer 580 may surround the first channel 730A. That is, the gate insulating layer 550 may completely surround the first channel 730A. The gate electrode layer 580 may surround the entire side of the first channel 730A. The gate electrode layer 580 may have a shape surrounding the first channel 730A in a closed path. Accordingly, the seventh transistor 700 may have a so-called all-around gate structure.

The first channel 730A in the first cross-section illustrated in FIG. 12 and the first channel 730A in the second cross-section illustrated in FIG. 13 may be provided alternately in a direction perpendicular to the substrate 520. The insulating layer 780 may be inside the first channel 730A. In some embodiments, the inside of the first channel 730A may be filled with the insulating layer 780, but the examples are not limited thereto.

Because the seventh transistor 700 is an MBCFET having a multi-bridge channel like the fifth transistor 500, the seventh transistor 700 may also have the same effect as described in the fifth transistor 500.

FIG. 14 illustrates an eighth transistor 800 according to at least one embodiment.

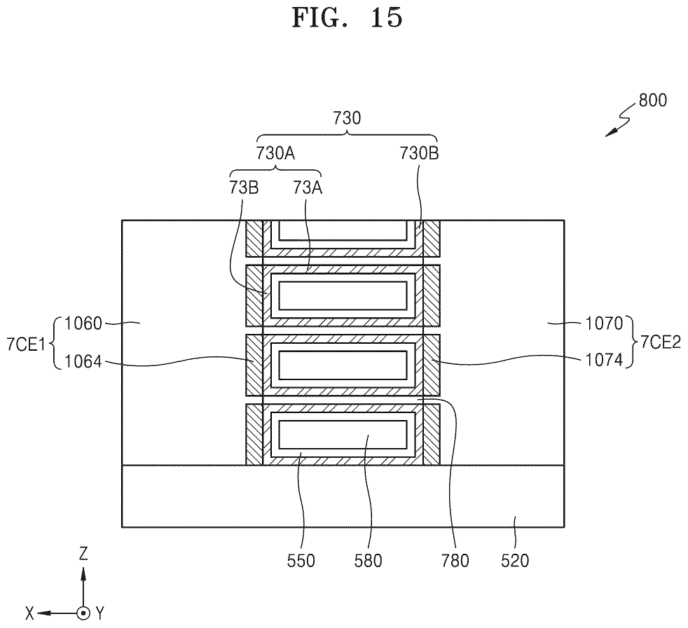

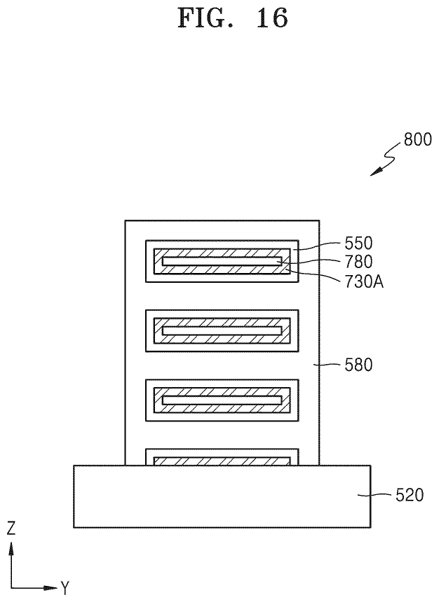

FIG. 15 illustrates a cross-section taken along direction 15-15′ in FIG. 14. FIG. 16 illustrates a cross-section taken along direction 16-16′ in FIG. 14.

Only portions different from the seventh transistor 700 will be described with reference to FIGS. 14 to 16.

The eighth transistor 800 does not include the low-k fifth dielectric layer 740 between the channel layer 730 and the gate insulating layer 550. Accordingly, the channel layer 730 and the gate insulating layer 550 in the eighth transistor 800 may be in direct contact with each other. The other configurations of the eighth transistor 800 may be the same as those of the seventh transistor 700.

Next, methods of manufacturing transistors according to embodiments will be described.

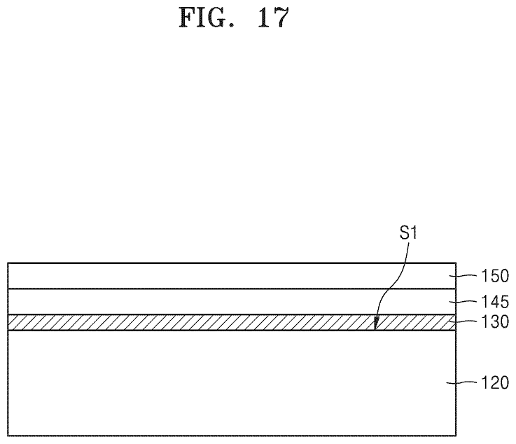

FIGS. 17 to 20 illustrate a manufacturing method according to at least one embodiment.

The manufacturing method illustrated in FIGS. 17 to 20 may be an example of a method of manufacturing the first transistor 100.

The same reference numerals as those described in the first transistor 100 denote the same members, and a description thereof is omitted.

Referring to FIG. 17, a channel layer 130, a protective layer 145, and a second dielectric layer 150 may be sequentially formed on one surface S1 of a substrate 120.

In some embodiments, the protective layer 145 may be a material layer for preventing the channel layer 130 from being damaged in a subsequent transistor manufacturing process (e.g., a source/drain forming process). The protective layer 145 may be in contact with the channel layer 130 and may be formed to cover the entire channel layer 130. In some embodiments, the protective layer 145 may be formed by chemical vapor deposition (CVD) or physical vapor deposition (PVD), but the examples are not limited thereto. In some embodiments, the protective layer 145 may be formed to have a thickness of 5 nm or less. For example, the protective layer 145 may be formed to have a thickness of about 0.5 nm to about 2 nm, but the examples are not limited thereto. For example, as described below in further detail, a portion of the protective layer 145 may be used to form a silicide layer in a subsequent silicide process, and the thickness of the protective layer 145 may influence the thickness of the silicide layer. Accordingly, the thickness of the protective layer 145 may be determined by taking into account the thickness of the silicide layer to be formed.

The protective layer 145 may include a material that has a low chemical reaction with the channel layer 130 in a heat treatment process that may be undergone in a transistor manufacturing process. For example, in some embodiments, when the channel layer 130 includes a 2D semiconductor material, the protective layer 145 may be or include a material layer including a semiconductor material. For example, the protective layer 145 may be or include a silicon layer or a germanium layer. In some embodiments, the silicon layer or the germanium layer may be a layer undoped or doped with a semiconductor doping material.

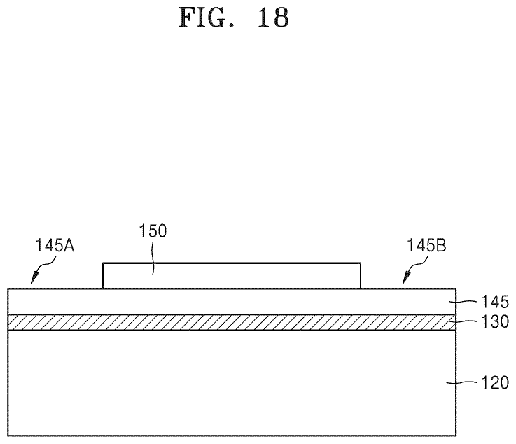

Next, as illustrated in FIG. 18, first and second portions 145A and 145B of the protective layer 145 may be exposed by removing a portion of the second dielectric layer 150. The process of removing a portion of the second dielectric layer 150 may use a photolithography process used in a semiconductor device manufacturing process. The first and second portions 145A and 145B may be spaced apart from each other with the second dielectric layer 150 therebetween. One of the first and second portions 145A and 145B may be a portion in which a source electrode is to be formed in a subsequent process, and the other of the first and second portions 145A and 145B may be a portion in which a drain electrode is to be formed in a subsequent process.

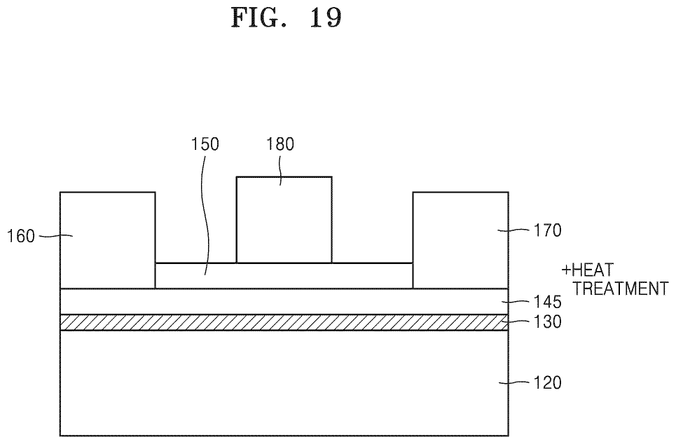

Next, as illustrated in FIG. 19, a first conductive layer 160 may be formed on the first portion 145A of the protective layer 145, and a second conductive layer 170 may be formed on the second portion 145B. The first conductive layer 160 may be formed to completely cover the first portion 145A, and the second conductive layer 170 may be formed to completely cover the second portion 145B. A gate electrode layer 180 may be formed on the second dielectric layer 150. The gate electrode layer 180 may be formed to be spaced apart from the first and second conductive layers 160 and 170. The first and second conductive layers 160 and 170 and the gate electrode layer 180 may or may not be formed simultaneously.

The first and second conductive layers 160 and 170 and the gate electrode layer 180 may be formed by using various deposition apparatuses used for depositing a material layer. For example, a CVD apparatus or a PVD apparatus may be used, or a sputter may be used, but the examples are not limited thereto.

The first and second conductive layers 160 and 170 are formed at positions spaced apart from each other on the channel layer 130, but are not in direct contact with the channel layer 130 due to the protective layer 145. As described above, because the first and second conductive layers 160 and 170 are formed on the channel layer 130 with the protective layer 145 therebetween, a damage to the channel layer 130 in the process of forming the first and second conductive layers 160 and 170 may be prevented or minimized.

Thereafter, a resulting structure in which the first and second conductive layers 160 and 170 and the gate electrode layer 180 are formed may be heat-treated at a set temperature. The heat treatment may be performed by using a heat treatment apparatus (e.g., a chamber or a furnace). In some embodiments, the heat treatment may include heat treatment for forming silicide. In some embodiments, the heat treatment may be performed at a temperature sufficient to form silicide by bonding a semiconductor component (e.g., Si or Ge) of the protective layer 145 to metal components of the first and second conductive layers 160 and 170. In some embodiments, the heat treatment may be performed in a temperature range of about 300° C. to about 600° C. and/or about 400° C. to about 600° C., but the examples are not limited thereto. The heat treatment may be performed within about 1 hour at a set temperature, but the examples are not limited thereto. For example, the heat treatment may be performed within about 30 minutes. In some embodiments, the heat treatment may be performed for about 10 minutes. The heat treatment time may be set based on the heat treatment temperature and the thickness of the protective layer 145.

The heat treatment may be performed until the entire portion formed under the first and second conductive layers 160 and 170 of the protective layer 145 is silicided.

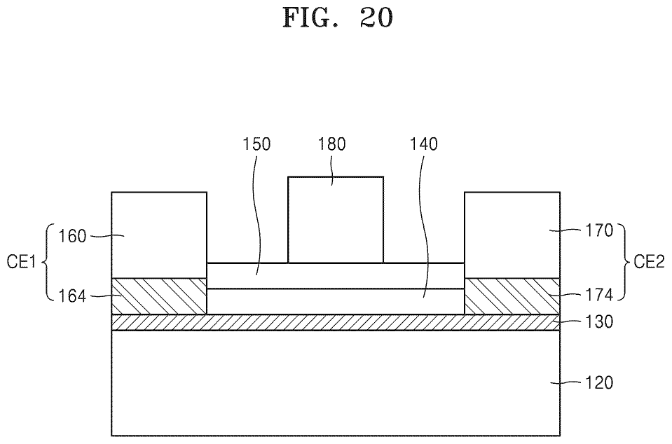

Due to the heat treatment, first and second silicide layers 164 and 174 may be respectively formed between the channel layer 130 and the first and second conductive layers 160 and 170, as illustrated in FIG. 20. Because the first and second silicide layers 164 and 170 are formed, work function modulation and conductivity may be improved, and thus, contact resistance between the first and second conductive layers 160 and 170 and the channel layer 130 may also be reduced.

The first silicide layer 164 and the first conductive layer 160 may form a first composite electrode layer (source electrode) CE1, and the second silicide layer 174 and the second conductive layer 170 may form a second composite electrode layer (drain electrode) CE2.

In FIG. 19, oxygen may be supplied to the portion formed under the second dielectric layer 150 of the protective layer 145 in the heat treatment for the silicidation and/or in a heat treatment process performed after the silicidation. As a result, the protective layer 145 under the second dielectric layer 150 may be oxidized and changed into the first dielectric layer 140, as illustrated in FIG. 20. In some embodiments, when the protective layer 145 includes a silicon layer, the first dielectric layer 140 may include a low-k silicon oxide layer (e.g., SiO₂).

Because the low-k first dielectric layer 140 is formed between the channel layer 130 and the second dielectric layer 150, remote phonon scattering may be suppressed or prevented, and thus, operating characteristics of the transistor may be improved.

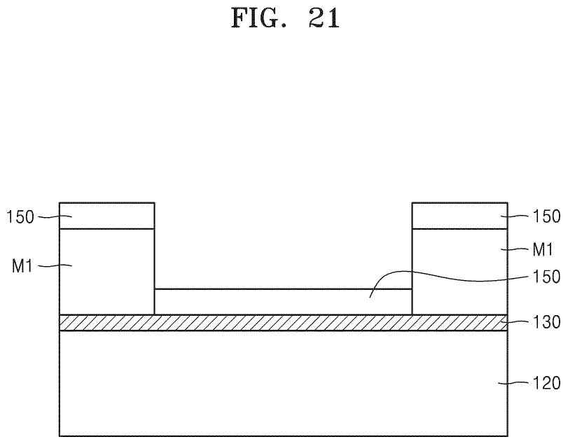

FIGS. 21 to 25 illustrate step-by-step procedures of a method of manufacturing a transistor, according to at least one embodiment.

The manufacturing method illustrated in FIGS. 21 to 25 may be an example of a method of manufacturing the second transistor 200.

The same reference numerals as those described in the first transistor 100 denote the same members, and a description thereof is omitted.

As illustrated in FIG. 21, a channel layer 130 may be formed on one surface S1 of a substrate 120. A mask pattern M1 defining an area where a second dielectric layer 150 is to be formed may be formed on the channel layer 130. The mask pattern M1 may be a photoresist pattern. The second dielectric layer 150 may be formed on the area of the channel layer 130 defined by the mask pattern M1. The second dielectric layer 150 may be in contact with the defined area and may be formed to completely cover the defined area. In the process of forming the second dielectric layer 150, the second dielectric layer 150 may also be formed on the mask pattern M1.

In some embodiments, a protective layer (e.g., 145 of FIG. 17) may be further formed between the channel layer 130 and the second dielectric layer 150.

After the second dielectric layer 150 is formed, the mask pattern M1 may be removed. When the mask pattern MI is removed, the second dielectric layer 150 formed on the mask pattern M1 may also be removed.

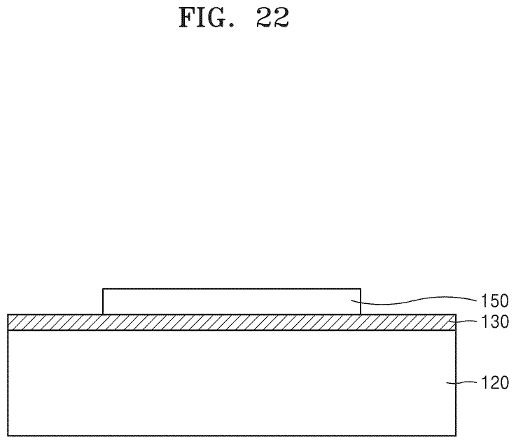

FIG. 22 illustrates a resulting structure from which the mask pattern M1 is removed.

After the mask pattern M1 is removed, the second dielectric layer 150 may be present only on a portion of the channel layer 130 and the channel layer 130 around the second dielectric layer 150 may be exposed. The exposed portions of the channel layer 130 may be spaced apart from each other with the second dielectric layer 150 therebetween.

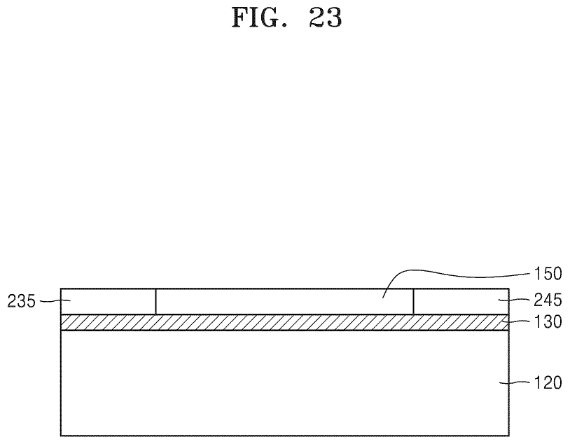

Next, as illustrated in FIG. 23, a first protective layer 235 may be formed on one of the exposed portions of the channel layer 130, and a second protective layer 245 may be formed on the other portion of the exposed portions of the channel layer 130. The first and second protective layers 235 and 245 may or may not be formed simultaneously. In some embodiments, the first and second protective layers 235 and 245 may be formed by the process of forming the protective layer 145 described with reference to FIG. 17, but the examples are not limited thereto. The first and second protective layers 235 and 245 may or may not be formed to have substantially the same thickness as that of the second dielectric layer 150. In some embodiments, the heights of the top surfaces of the first and second protective layers 235 and 245 may be equal to or different from the height of the top surface of the second dielectric layer 150. In some embodiments, the first and second protective layers 235 and 245 may be formed to overlap a portion of the second dielectric layer 150 in a range in which the first and second protective layers 235 and 245 are not in contact with a gate electrode layer to be formed. In some embodiments, examples of the thicknesses and materials of the first and second protective layers 235 and 245 may follow the examples of the thickness and material of the protective layer 145 of FIG. 17.

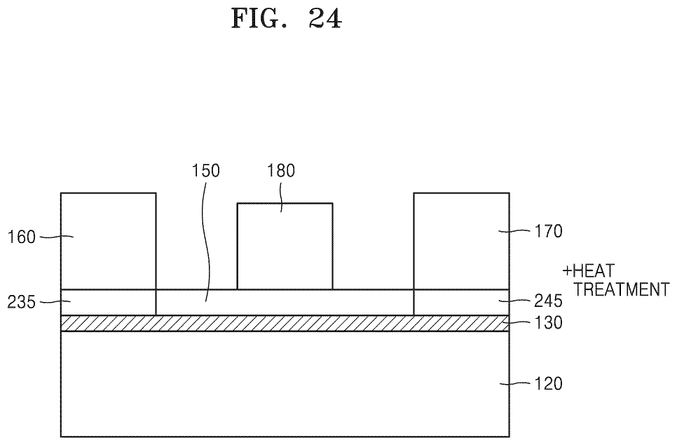

Next, as illustrated in FIG. 24, a first conductive layer 160 may be formed on the first protective layer 235, a second conductive layer 170 may be formed on the second protective layer 245, and a gate electrode layer 180 may be formed on the second dielectric layer 150. In some embodiments, the first conductive layer 160 may be formed to cover the entire top surface of the first protective layer 235, or may be formed to cover only a portion of the top surface of the first protective layer 235. In some embodiments, the second conductive layer 170 may be formed to cover the entire top surface of the second protective layer 245, or may be formed to cover only a portion of the top surface of the second protective layer 245.

Because the first and second conductive layers 160 and 170 are respectively formed on the first and second protective layers 235 and 245, a damage to the channel layer 130 in the process of forming the first and second conductive layers 160 and 170 may be limited and/or prevented.

In some embodiments, the first and second conductive layers 160 and 170 and the gate electrode layer 180 may or may not be formed simultaneously. For example, the gate electrode layer 180 may be formed after the first and second conductive layers 160 and 170 are formed, and/or vice versa.

After the first and second conductive layers 160 and 170 and the gate electrode layer 180 are formed, heat treatment may be performed on the resulting structure. The heat treatment may be performed according to the heat treatment described above with reference to FIG. 19. A silicide reaction may occur between the first protective layer 235 and the first conductive layer 160 and between the second protective layer 245 and the second conductive layer 170, according to the heat treatment. The silicide reaction may continue until the first and second protective layers 235 and 245 completely disappear.

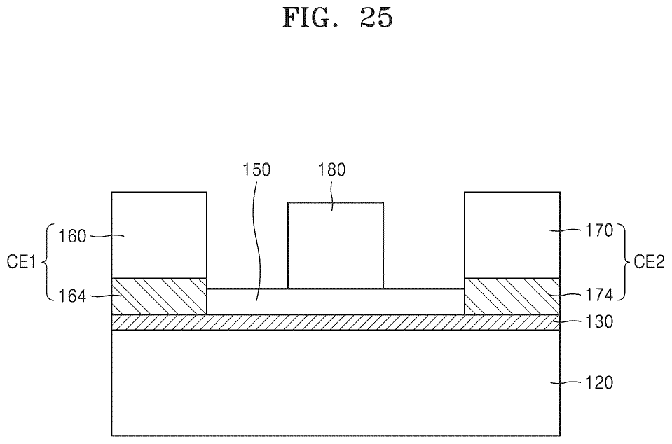

As a result, as illustrated in FIG. 25, a first silicide layer 164 may be formed between the first conductive layer 160 and the channel layer 130, and a second silicide layer 164 may be formed between the second conductive layer 170 and the channel layer 130, according to the heat treatment. Accordingly, as described above with reference to FIG. 20, the contact resistance between the first and second conductive layers 160 and 170 and the channel layer 130 may be reduced.

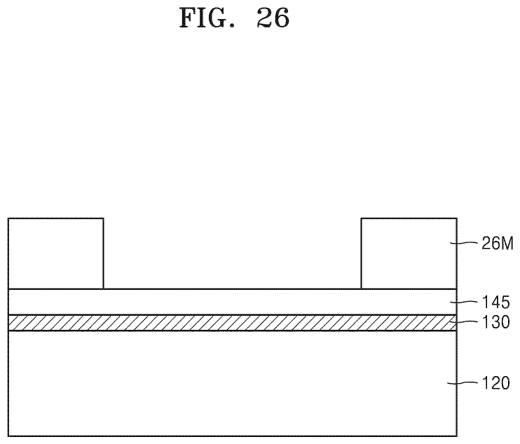

FIGS. 26 to 28 are cross-sectional views illustrating a part of a method of manufacturing a transistor, according to at least one embodiment.

Referring to FIG. 26, a channel layer 130 and a protective layer 145 may be sequentially formed on a substrate 120. A mask pattern 26M defining an area in which a gate insulating layer is to be formed may be formed on the protective layer 145. A portion of the protective layer 145 corresponding to the area in which the gate insulating layer is to be formed may be exposed by the mask pattern 26M.

The exposed portion of the protective layer 145 may be removed by etching, e.g., wet etching. In the wet etching, an etchant having a high etching selectivity with respect to the protective layer 145 may be used. The wet etching may be performed until the channel layer 130 is exposed.

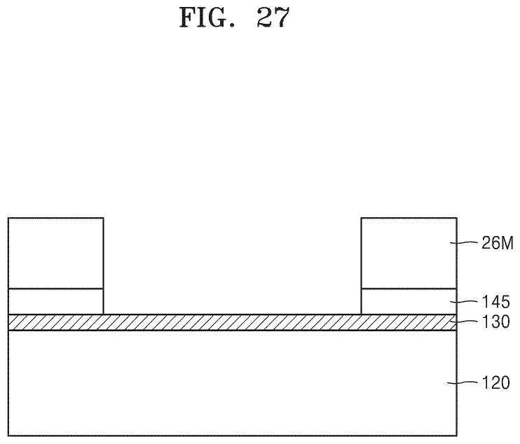

As illustrated in FIG. 27, due to the wet etching, the exposed portion of the protective layer 145 may be removed, the channel layer 130 between the mask patterns 26M may be exposed, and the protective layer 145 may remain only between the mask pattern 26M and the channel layer 130.

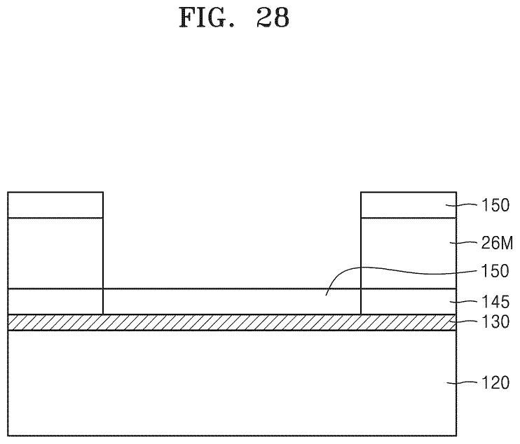

As illustrated in FIG. 28, after the wet etching, a gate insulating layer 150 may be formed on the exposed portion of the channel layer 130 in the presence of the mask pattern 26M. At this time, the gate insulating layer 150 may also be formed on the mask pattern 26M.

After the gate insulating layer 150 is formed on the exposed portion of the channel layer 130, the mask pattern 26M may be removed. When the mask pattern 26M is removed, the gate insulating layer formed thereon may also be removed. Subsequent processes may proceed according to the processes described above with reference to FIG. 24.

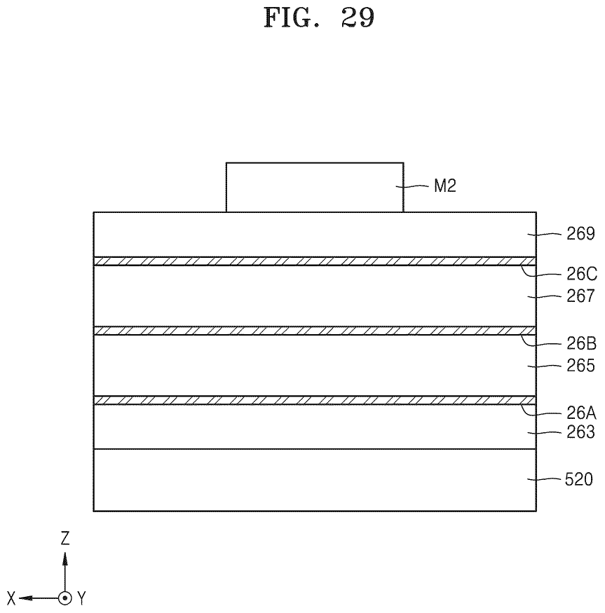

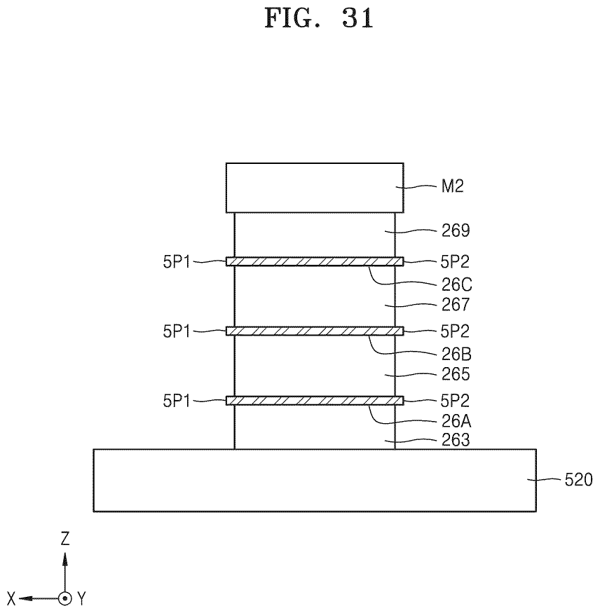

FIGS. 29 to 38 illustrate step-by-step procedures of a method of manufacturing a transistor, according to at least one embodiment.

The manufacturing method illustrated in FIGS. 29 to 38 may be an example of a method of manufacturing the fifth transistor 500.

FIGS. 29 to 38 may illustrate the manufacturing process viewed from the cross-section taken along direction 6-6′ in FIG. 5.

The same reference numerals as those described in the fifth transistor 500 denote the same members, and a description thereof is omitted.

Referring to FIG. 29, a first sacrificial layer 263, a first channel layer 26A, a second sacrificial layer 265, a second channel layer 26B, a third sacrificial layer 267, a third channel layer 26C, and a fourth sacrificial layer 269 may be sequentially formed on a substrate 520 in a direction (Z-axis direction) perpendicular to a top surface of the substrate 520. The second sacrificial layer 265 may be formed to completely cover the top surface of the first channel layer 26A. The third sacrificial layer 267 may be formed to completely cover the top surface of the second channel layer 26B. The fourth sacrificial layer 269 may be formed to completely cover the top surface of the third channel layer 26C. The first to third channel layers 26A to 26C may or may not be arranged at regular intervals in the vertical direction. The lengths of the first to third channel layers 26A to 26C in the horizontal direction (X-axis direction) may be equal to or substantially equal to each other.

In some embodiments, only one or two of the first to third channel layers 26A to 26C may be provided. In some embodiments, a greater number of channel layers than the three channel layers 26A to 26C may be provided.

In some embodiments, when the channel layers sequentially arranged on the substrate 520 are collectively referred to as one channel layer, each of the channel layers may be referred to as a sub-channel layer.

In some embodiments, the layer structures and materials of the first to third channel layers 26A to 26C may be the same as and/or substantially similar to the layer structure and material of the channel layer 130 described in the first transistor 100. In some embodiments, the materials of the channel layers 26A to 26C may be different from each other within the material of the channel layer 130 of the first transistor 100.

In some embodiments, the first to fourth sacrificial layers 263, 265, 267, and 269 may be layers including the same material as each other. In some embodiments, the first to fourth sacrificial layers 263, 265, 267, and 269 may each include SiO₂, Al₂O₃, HfO₂, and/or Si₃N₄.

The number of sacrificial layers may increase or decrease in proportion to the number of channel layers.

A mask pattern M2 defining a partial area of the fourth sacrificial layer 269 may be formed on the fourth sacrificial layer 269. In some embodiments, the mask pattern M2 may include a photoresist pattern, but the examples are not limited thereto. An area in which a channel-gate stack including an MBC and a gate stack is to be formed may be defined by the mask pattern M2.

After the mask pattern M2 is formed, the sacrificial layers 263, 265, 267, and 269 and the channel layers 26A to 26C around the mask pattern M2 may be etched. The etching may be performed by using, e.g., dry etching, and may be performed until the substrate 520 is exposed.

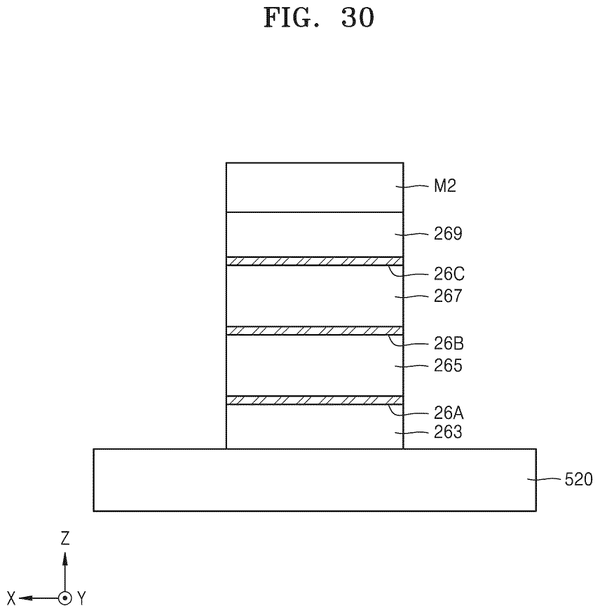

FIG. 30 illustrates a result of the etching.

Next, the resulting structure of FIG. 30 in which the etching is completed may be wet-etched. The wet etching may be performed on the sacrificial layers 263, 265, 267, and 269. Accordingly, an etchant having a relatively high etching selectivity for the sacrificial layers 263, 265, 267, and 269 may be used as an etchant used for the wet etching. In some embodiments, the etchant may include at least one of, e.g., HF, HCl, NH₄OH, and/or H₂PO₄. The wet etching may be performed until the channel layers 26A to 26C partially protrude to the side. The degree (length) of the channel layers 26A to 26C protruding to the side by the wet etching may be adjusted by controlling a wet etching time. The wet etching may be performed until the channel layers 26A to 26C protrude by a set length. After the wet etching, a first portion 5P1 of each of the channel layers 26A to 26C protrudes in a first direction (+X-axis direction), and a second portion 5P2 of each of the channel layers 26A to 26C protrudes in a direction opposite to the first direction. As a result, both sides of each of the channel layers 26A to 26C partially protrude due to the wet etching. As a natural result of the wet etching, after the wet etching, the widths of the sacrificial layers 263, 265, 267, and 269 in the first direction are less than the widths of the channel layers 26A to 26C.

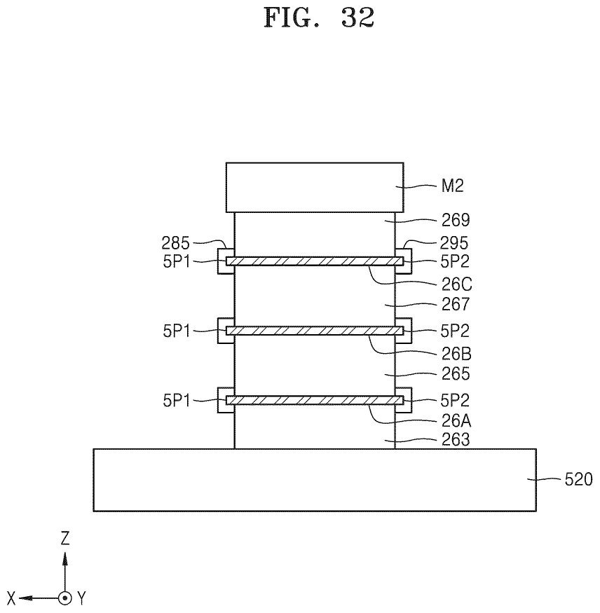

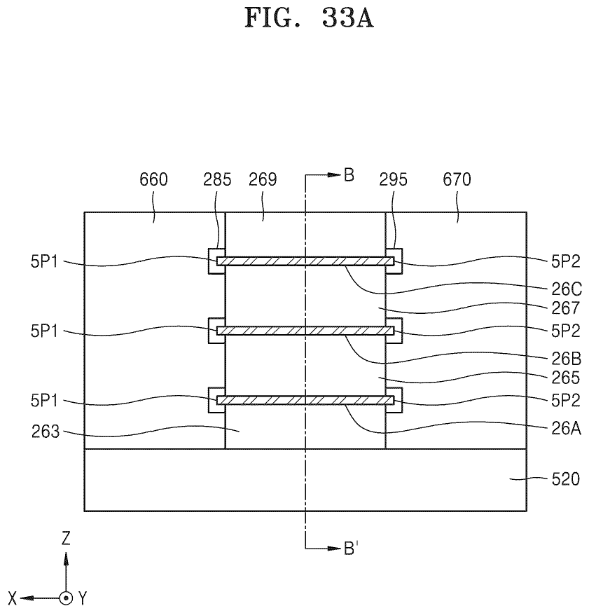

As illustrated in FIG. 32, after the wet etching is completed, a first protective layer 285 covering the first portion 5P1 of each of the channel layers 26A to 26C and a second protective layer 295 covering the second portion 5P2 of each of the channel layers 26A to 26C may be formed on both sides of each of the sacrificial layers 263, 265, 267, and 269. The first and second protective layers 285 and 295 may be in direct contact with the first and second portions 5P1 and 5P2 and may be formed to completely cover the first and second portions 5P1 and 5P2, respectively. The first and second protective layers 285 and 295 may be formed of (and/or include) a semiconductor compound (e.g., Si and/or Ge). The thicknesses of the first and second protective layers 285 and 295 may be formed to correspond to the thickness of the protective layer 145 of FIG. 18, but may be less than or greater than the thickness of the protective layer 145 of FIG. 18. The thicknesses of the first and second protective layers 285 and 295 may be determined by considering a thickness of a silicide layer to be formed in a subsequent process. The materials of the first and second protective layers 285 and 295 may be the same as and/or substantially similar to the material of the protective layer 145 described above with reference to FIG. 18. In some embodiments, the materials of the first and second protective layers 285 and 295 may be different from each other.

In some embodiments, in the process of forming the first protective layer 285, the first protective layers 285 adjacent to each other may be formed to be connected to each other. For example, the first protective layer 285 may be formed on the entire left side surface of each the sacrificial layers 263, 265, 267, and 269 on which the first protective layer 285 is to be formed, and the second protective layer 295 may be formed on the entire right side of each of the sacrificial layers 263, 265, 267, and 269 on which the second protective layer 295 is to be formed.

Because the protruding first and second portions 5P1 and 5P2 of each of the channel layers 26A to 26C are completely covered with the first and second protective layers 285 and 295, a damage to the channel layers 26A to 26C in a subsequent process of forming source/drain electrodes may be limited and/or prevented.

In some embodiments, the first and second protective layers 285 and 295 may be deposited by CVD, but the examples are not limited thereto.

After the first and second protective layers 285 and 295 are formed, the mask pattern M2 may be removed.

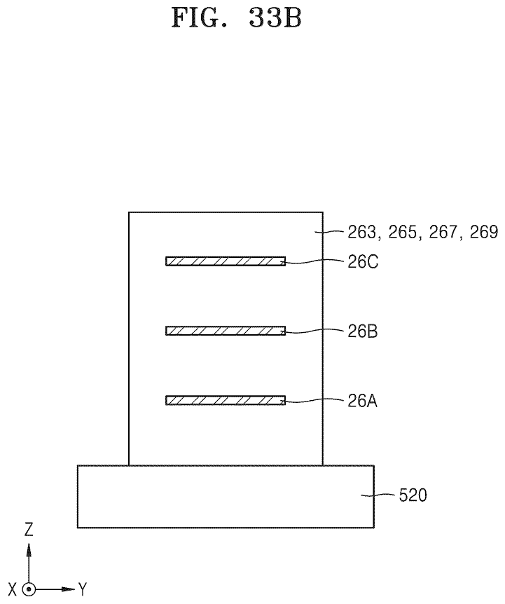

Next, as illustrated in FIGS. 33A and 33B, first and second conductive layers 660 and 670 may be formed on both sides of each of the sacrificial layers 263, 265, 267, and 269. FIG. 33B is a cross-sectional view taken along direction B-B′ in FIG. 33A.

The first conductive layer 660 may be formed to completely cover the first protective layer 285 and completely cover the side surfaces of the sacrificial layers 263, 265, 267, and 269 around the first protective layer 285. The first conductive layer 660 may be in direct contact with the first protective layer 285.

The second conductive layer 670 may be formed to completely cover the second protective layer 295 and completely cover the side surfaces of the sacrificial layers 263, 265, 267, and 269 around the second protective layer 295. The second conductive layer 670 may be in direct contact with the second protective layer 295. In some embodiments, the first and second conductive layers 660 and 670 may be formed by the same deposition process as used to form the first and second conductive layers 160 and 170 of FIG. 19, and may also be formed by other processes.

Heat treatment may be performed on a resulting structure of FIGS. 33A and 33B in which the first and second conductive layers 660 and 670 are formed. This heat treatment may be for a silicide reaction between the first and second conductive layers 660 and 670 and the first and second protective layers 285 and 295. This heat treatment may be performed until the first and second protective layers 285 and 295 are all silicided. In some embodiments, the heat treatment may be performed according to the heat treatment described above with reference to FIG. 19.

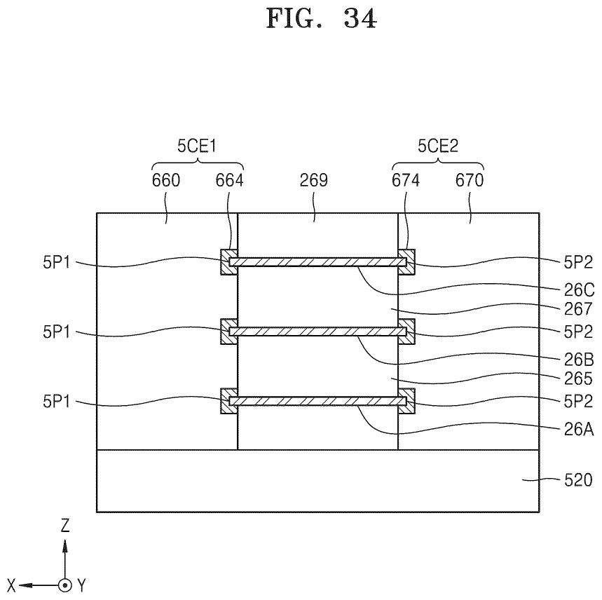

As a result of the heat treatment performed on the resulting structure illustrated in FIGS. 33A and 33B, the first and second protective layers 285 and 295 may be silicided so that, as shown in FIG. 34, first and second silicide layers 664 and 674 are formed at the sites of the first and second protective layers 285 and 295. A combination of the first conductive layer 660 and the first silicide layer 664 is a composite electrode layer and may correspond to the first electrode layer 5CE1 of the fifth transistor 500. A combination of the second conductive layer 670 and the second silicide layer 674 is also a composite electrode layer and may correspond to the second electrode layer 5CE2 of the fifth transistor 500.

After the first and second silicide layers 664 and 674 are formed, the sacrificial layers 263, 265, 267, and 269 may be removed. The sacrificial layers 263, 265, 267, and 269 may be removed by using second wet etching. The second wet etching may be performed until the sacrificial layers 263, 265, 267, and 269 are completely removed. The second wet etching may be performed according to the wet etching applied to the side etching of the sacrificial layers 263, 265, 267, and 269 described above with reference to FIG. 30, but the examples are not limited thereto.

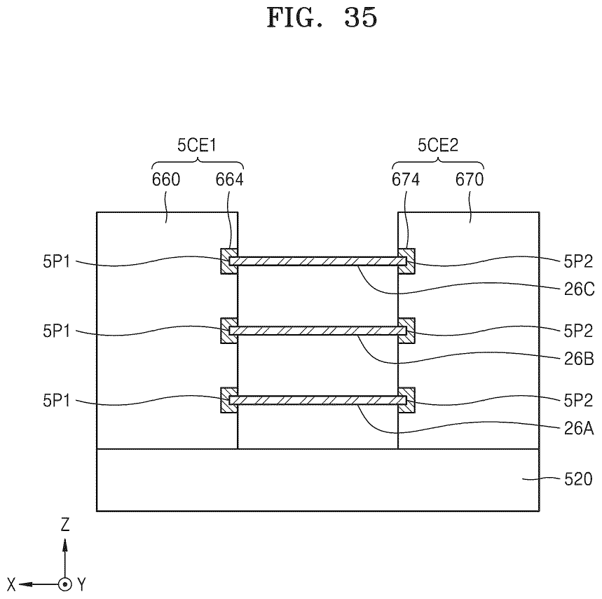

FIG. 35 illustrates a result of the second wet etching.

Referring to FIG. 35, the sacrificial layers 263, 265, 267, and 269 above and below the channel layers 26A to 26C are completely removed, and the shape of the channel layers 26A to 26C as a multi-bridge connecting the first electrode layer 5CE1 and the second electrode layer 5CE2 to each other is revealed. When the sacrificial layers 263, 265, 267, and 269 are completely removed, empty spaces may exist above and below the channel layers 26A to 26C.

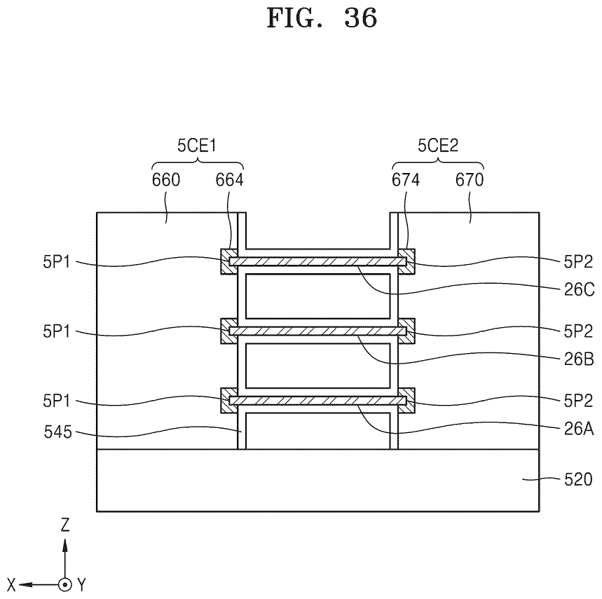

After the sacrificial layers 263, 265, 267, and 269 are completely removed, a first material layer 545 may be formed on the entire exposed surfaces of the channel layers 26A to 26C, as illustrated in FIG. 36. For example, the first material layer 545 may be directly formed on the entire exposed surfaces (e.g., the top, bottom, and side surfaces) of the channel layers 26A to 26C between the first electrode layer 5CE1 and the second electrode layer 5CE2. The first material layer 545 may be formed to cover the entire surfaces of the channel layers 26A to 26C. In some embodiments, because the first material layer 545 is formed on the entire exposed surfaces of the channel layers 26A to 26C, the first material layer 545 may also be formed on the inner surfaces of the first and second electrode layers 5CE1 and 5CE2, (e.g., the inner surfaces of the first and second electrode layers 5CE1 and 5CE2 in contact with the channel layers 26A to 26C). The inner surfaces of the first and second electrode layers 5CE1 and 5CE2 may face each other with the channel layers 26A to 26C therebetween. In some embodiments, the first material layer 545 may be formed to cover the entire inner surfaces of the first and second electrode layers 5CE1 and 5CE2. Accordingly, the first material layer 545 may be in contact with the first silicide layer 664 of the first electrode layer 5CE1 and the first conductive layer 660 therearound, and may be in contact with the second silicide layer 674 of the second electrode layer 5CE2 and the second conductive layer 670 therearound.

In some embodiments, the first material layer 545 may be formed by using CVD or atomic layer deposition (ALD), but the examples are not limited thereto. In some embodiments, the first material layer 545 may be formed to have a thickness of 5 nm or less. For example, the first material layer 545 may be formed to have a thickness of about 0.5 nm to about 2 nm, but the examples are not limited thereto.

In some embodiments, the first material layer 545 may include a material selected to form a low-k dielectric having a relatively low permittivity by reacting with oxygen through heat treatment. For example, in some embodiments, the first material layer 545 may include Si or Ge, but the examples are not limited thereto. In some embodiments, the heat treatment may be heat treatment for the first material layer 545. In some embodiments, the heat treatment may include supplying oxygen in various subsequent processes after the first material layer 545 is formed and oxidizing the first material layer 545.

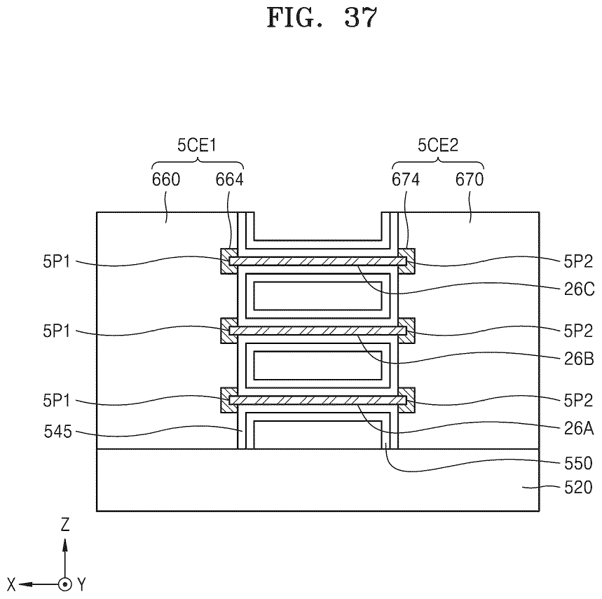

After the first material layer 545 is formed, a second dielectric layer 550 may be formed on the first material layer 545, as illustrated in FIG. 37. The second dielectric layer 550 may be formed by using the same method as used to form the first material layer 545, and/or may be formed by other methods. The second dielectric layer 550 may be directly formed on the entire inner surfaces of the first material layer 545 and on the entire top and bottom surfaces of the first material layer 545 between the inner surfaces of the first material layer 545, that is, the surfaces continuing to the inner surfaces of the first material layer 545. The second dielectric layer 550 may include a high-k dielectric layer that may be used as a gate insulating layer, such as aluminum oxide, hafnium oxide, titanium oxide, and/or the like.

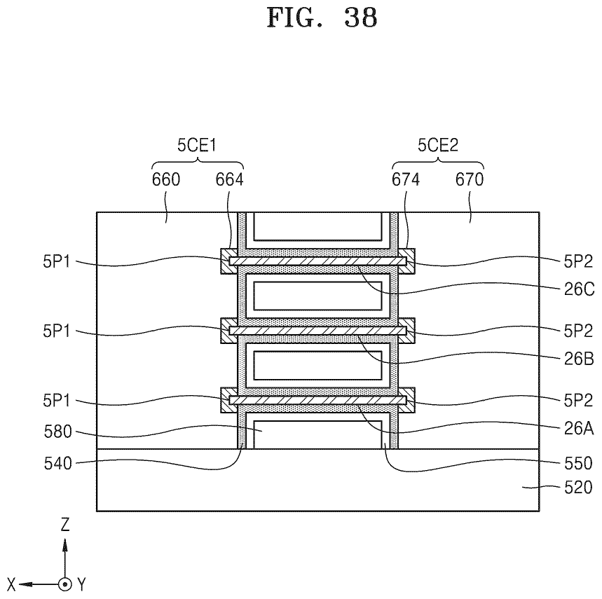

After the second dielectric layer 550 is formed, a gate electrode layer 580 may be formed on the second dielectric layer 550, as illustrated in FIG. 38. The gate electrode layer 580 may be formed on the inner surfaces of the second dielectric layer 550 and the top and bottom surfaces of the second dielectric layer 550 therebetween. The gate electrode layer 580 may or may not be formed to completely fill the space between the channel layers 26A to 26C remaining after the second dielectric layer 550 is formed.

While the second dielectric layer 550 and/or the gate electrode layer 580 are formed. the first material layer 545 may be transformed into a first dielectric layer 540.

Through these processes, the fifth transistor 500 may be formed.

In some embodiments, the process of forming the first material layer 545 may be omitted in the process of manufacturing the fifth transistor 500 described above, and as a result, the sixth transistor 600 may be formed.

The configuration of the third transistor 300, which is the fin-type FET, may be the same as the configuration of the second transistor 200, except that the fin-type insulating layer 325 is first provided on the substrate 320. Accordingly, the third transistor 300 may be manufactured by forming the fin-type insulating layer 325 on the substrate 320 and then performing the method of manufacturing the planar-type FET as illustrated in FIGS. 21 to 25.

In the same manner, the fourth transistor 400, which is the fin-type FET, may be manufactured by forming the fin-type insulating layer 325 on the substrate 320 and then performing the method of manufacturing the planar-type FET as illustrated in FIGS. 17 to 20.

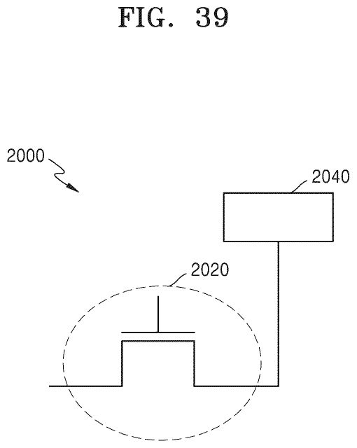

FIG. 39 illustrates an electronic device 2000 according to at least one embodiment. In some embodiments, the electronic device 2000 may be a memory device.

Referring to FIG. 39, the electronic device 2000 may include a switching element 2020 and a data storage 2040 connected thereto. In some embodiments, the switching element 2020 may include one of the transistors according to the embodiments described above. In some embodiments, the data storage 2040 may include a data storage unit used in a volatile or non-volatile memory device. For example, the data storage 2040 may include a capacitor, and/or may include a magnetoresistive layer, a phase change layer, and/or the like.

Next, an electronic apparatus (apparatuses) according to at least one embodiment will be described. The electronic apparatus (apparatuses) according to at least one embodiment may include the transistor or the electronic device according to the embodiments described above.

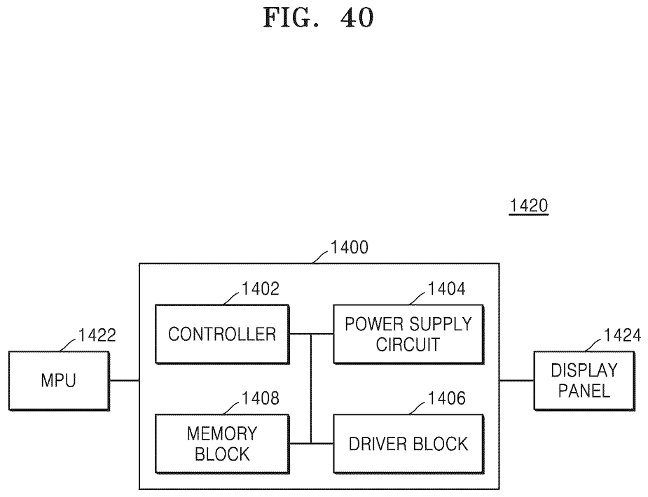

FIG. 40 is a schematic block diagram of a display driver integrated circuit (IC) (DDI) 1400 and a display apparatus 1420 including the DDI 1400, as a first electronic apparatus, according to at least one embodiment.

Referring to FIG. 40, the DDI 1400 may include a controller 1402, a power supply circuit 1404, a driver block 1406, and a memory block 1408. The controller 1402 may receive a command applied from a main processing unit (MPU) 1422, may decode the received command, and may control the respective blocks of the DDI 1400 to implement operations according to the command. The power supply circuit 1404 may generate a driving voltage in response to the control of the controller 1402. The driver block 1406 may drive a display panel 1424 by using the driving voltage generated by the power supply circuit 1404 in response to the control of the controller 1402. The display panel 1424 may be a liquid crystal display panel or a plasma display panel. The memory block 1408 is a block that temporarily stores commands input to the controller 1402 or control signals output from the controller 1402 or stores necessary data, and may include a volatile memory (e.g., random access memory (RAM)) and/or a non-volatile memory. In some embodiments, the controller 1402 may include the electronic device (e.g., the electronic device 2000 of FIG. 39) according to the embodiment described above. In some embodiments, the parts and/or blocks included in the DDI 1400 may each include a switching element, and the switching element may include one of the transistors according to the embodiments described above.

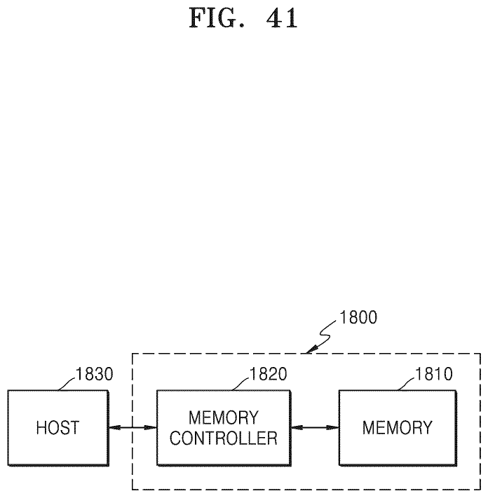

FIG. 41 is a block diagram of an electronic system 1800 as a second electronic apparatus, according to at least one embodiment.

Referring to FIG. 41, the electronic system 1800 may include a memory 1810 and a memory controller 1820. The memory controller 1820 may control the memory 1810 to read data from the memory 1810 and/or write data to the memory 1810 in response to a request from the host 1830.

In some embodiments, the memory 1810 may include the electronic device (e.g., the electronic device 2000 of FIG. 39) according to the embodiment described above. In some embodiments, the memory 1810 and the memory controller 1820 of the electronic system 1800 may each include a switching element, and the switching element may include one of the transistors according to the embodiments described above.

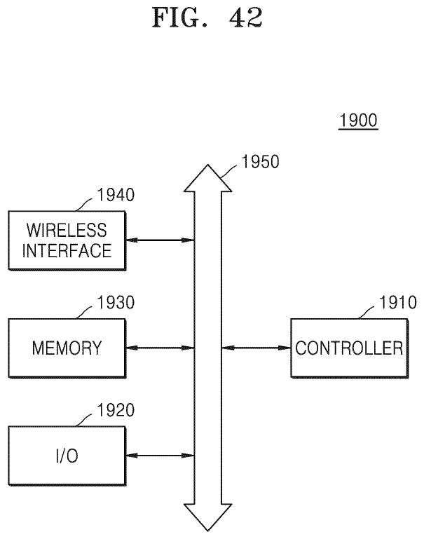

FIG. 42 is a block diagram of an electronic system 1900 as a third electronic apparatus, according to at least one embodiment.

Referring to FIG. 42, the electronic system 1900 may configure a wireless communication system or a system capable of transmitting and/or receiving information in a wireless environment. The electronic system 1900 may include a controller 1910, an input/output (I/O) device 1920, a memory 1930, and a wireless interface 1940, which are interconnected to each other through a bus 1950.

The controller 1910 may include at least one of a microprocessor, a digital signal processor, or a processing device similar thereto. The I/O device 1920 may include at least one of a keypad, a keyboard, or a display.

The memory 1930 may be used to store commands executed by controller 1910. For example, the memory 1930 may be used to store user data. In some embodiments, the memory 1930 may include the electronic device (e.g., the electronic device 2000 of FIG. 39) according to the embodiment described above.

In some embodiments, the elements 1910, 1920, 1930, and 1940 included in the electronic system 1900 may each include a switching element, and the switching element may include one of the transistors according to the embodiments described above.

The electronic system 1900 may use the wireless interface 1940 to transmit and receive data via a wireless communication network. The wireless interface 1940 may include an antenna and/or a wireless transceiver. In some embodiments, the electronic system 1900 may be used for a communication interface protocol of a 3^{rd} generation communication system, such as code division multiple access (CDMA), global system for mobile communications (GSM), north American digital cellular (NADC), extended-time division multiple access (E-TDMA), and/or wide band code division (WCDMA).

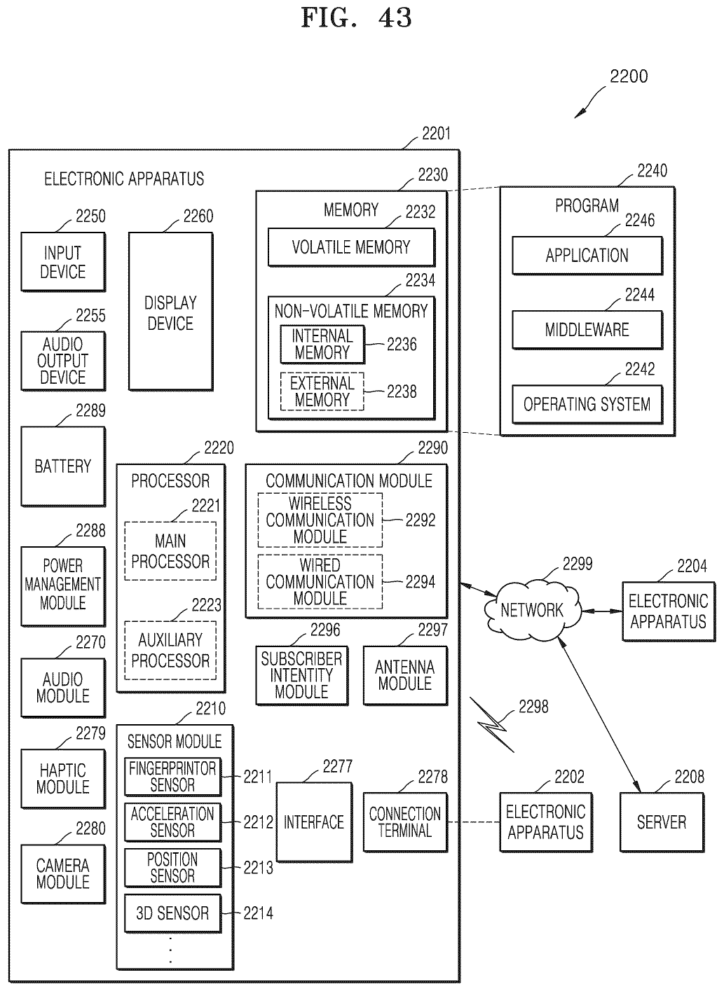

FIG. 43 is a block diagram illustrating a schematic configuration of a fourth electronic apparatus according to at least one embodiment.

Referring to FIG. 43, in a network environment 2200, the electronic apparatus 2201 may communicate with another electronic apparatus 2202 via a first network 2298 (a short-range wireless communication network, etc.), or may communicate with another electronic apparatus 2204 and/or a server 2208 via a second network 2299 (a long-range wireless communication network, etc.). For example, the electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identity module 2296, and/or an antenna module 2297. In the electronic apparatus 2201, some elements (e.g., the display device 2260, etc.) may be omitted and/or other elements may be added. Some elements may be implemented as one IC. For example, a fingerprint sensor 2211, an iris sensor, an illumination sensor, etc. of the sensor module 2210 may be embedded in the display device 2260 (a display, etc.).

The processor 2220 may execute software (e.g., a program 2240, etc.) to control one or more other elements (hardware and software elements, etc.) of the electronic apparatus 2201 connected to the processor 2220, and may perform various data processing or operations. As part of data processing or operations, the processor 2220 may load commands and/or data received from other elements (e.g., the sensor module 2210, the communication module 2290, etc.) into a volatile memory 2232, may process the commands and/or data stored in the volatile memory 2232, and may store result data in a non-volatile memory 2234. The processor 2220 may include a main processor 2221 (e.g., a central processing unit, an application processor, etc.) and an auxiliary processor 2223 configured to operate independently of or together with the main processor 2221 (e.g., a graphics processing unit, an image signal processor, a sensor hub processor, a communication processor, etc.). The auxiliary processor 2223 may use a smaller amount of power than the main processor 2221 and may perform a specialized function.

On behalf of the main processor 2221, while the main processor 2221 is in an inactive state (a sleep state), or together with the main processor 2221 while the main processor 2221 is in an active state (an application execution state), the auxiliary processor 2223 may control the functions and/or states related to some elements of the electronic apparatus 2201 (e.g., the display device 2260, the sensor module 2210, the communication module 2290, etc.), and the auxiliary processor 2223 (e.g., the image signal processor, the communication processor, etc.) may be implemented as part of other functionally related elements (e.g., the camera module 2280, the communication module 2290, etc.).

The memory 2230 may store a variety of data required by the elements of the electronic apparatus 2201 (e.g., the processor 2220, the sensor module 2276, etc.). The data may include, for example, the software (e.g., the program 2240, etc.) and input data and/or output data for commands related thereto. The memory 2230 may include the volatile memory 2232 and/or the non-volatile memory 2234. The non-volatile memory 2234 may include an internal memory 2236 and an external memory 2238. In some embodiments, the memory 2230 may include the electronic device (e.g., the electronic device 2000 of FIG. 39) according to the embodiment described above.

The program 2240 may be stored in the memory 2230 as software, and may include an operating system 2242, a middleware 2244, and/or an application 2246.

The input device 2250 may receive, from the outside (e.g., a user, etc.) of the electronic apparatus 2201, commands and/or data to be used by the elements (e.g., the processor 2220, etc.) of the electronic apparatus 2201. The input device 2250 may include a microphone, a mouse, a keyboard, and/or a digital pen (e.g., a stylus pen, etc.).

The audio output device 2255 may output a sound signal to the outside of the electronic apparatus 2201. The audio output device 2255 may include a speaker and/or a receiver. The speaker may be used for general purposes, such as multimedia playback or recording playback, and the receiver may be used to receive an incoming call. The receiver may be integrated as part of the speaker, or may be implemented as an independent separate device.

The display device 2260 may visually provide information to the outside of the electronic apparatus 2201. The display device 2260 may include a display, a hologram device. a projector, and/or the like, and a control circuit for controlling the corresponding device. In at least one embodiment, the display device 2260 may include a touch circuitry configured to sense a touch, and/or a sensor circuitry (e.g., a pressure sensor, etc.) configured to measure the intensity of force generated by the touch.

The audio module 2270 may convert a sound into an electrical signal or vice versa. The audio module 2270 may obtain a sound through the input device 2250, or may output a sound through the audio output device 2255 and/or, a speaker and/or a headphone of another electronic apparatus (e.g., the electronic apparatus 2202) directly or wirelessly connected to the electronic apparatus 2201.

The sensor module 2210 may sense an operating state (e.g., power, temperature, etc.) of the electronic apparatus 2201 or an external environmental state (e.g., a user state, etc.), and may generate an electrical signal and/or a data value corresponding to the sensed state. The sensor module 2210 may include the fingerprint sensor 2211, an acceleration sensor 2212, a position sensor 2213, a 3D sensor 2214, and the like. In addition, the sensor module 2210 may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, an illumination sensor, and/or the like.

The 3D sensor 2214 may sense a shape, a motion, etc. of a subject by emitting certain light to the subject and analyzing light reflected from the subject, and may include a meta optical element.

The interface 2277 may support one or more designated protocols that may be used by the electronic apparatus 2201 so as to directly or wirelessly connect to another electronic apparatus (e.g., the electronic apparatus 2202, etc.). The interface 2277 may include a high definition multimedia interface (HDMI), a universal serial bus (USB) interface, a secure digital (SD) card interface, an audio interface, and/or the like.

A connection terminal 2278 may include a connector through which the electronic apparatus 2201 may be physically connected to another electronic apparatus (e.g., the electronic apparatus 2202, etc.). The connection terminal 2278 may include an HDMI connector, a USB connector, an SD card connector, an audio connector (e.g., a headphone connector, etc.), and/or the like.

The haptic module 2279 may convert an electrical signal into a mechanical stimulus (e.g., vibration, movement, etc.) or an electrical stimulus which a user may recognize through a tactile or kinesthetic sense. The haptic module 2279 may include a motor, a piezoelectric element, an electrical stimulator, and/or the like.

The camera module 2280 may capture a still image and a moving image. The camera module 2280 may include a lens assembly including one or more lenses, image sensors, image signal processors, and/or flashes. The lens assembly included in the camera module 2280 may collect light emitted from a subject that is an image capture target.

The power management module 2288 may manage power supplied to the electronic apparatus 2201. The power management module 2288 may be implemented as part of a power management integrated circuit (PMIC).

The battery 2289 may supply power to the elements of the electronic apparatus 2201. The battery 2289 may include a non-rechargeable primary cell, a rechargeable secondary cell, and/or a fuel cell.

The communication module 2290 may establish a direct (wired) communication channel and/or a wireless communication channel between the electronic apparatus 2201 and another electronic apparatus (e.g., the electronic apparatus 2202, the electronic apparatus 2204, the server 2208, etc.), and may support communication through the established communication channel. The communication module 2290 may include one or more communication processors that operate independently of the processor 2220 (e.g., the application processor, etc.) and may support direct communication and/or wireless communication. The communication module 2290 may include a wireless communication module 2292 (e.g., a cellular communication module, a short-range wireless communication module, a global navigation satellite system (GNSS) communication module, etc.) and/or a wired communication module 2294 (e.g., a local area network (LAN) communication module, a power line communication module, etc.). The corresponding communication module among these communication modules may communicate with another electronic apparatus via the first network 2298 (e.g., a short-range communication network such as Bluetooth, Wi-Fi Direct, or Infrared data association (IrDA)) or the second network 2299 (e.g., a long-range communication network such as a cellular network, Internet, or a computer network (LAN, WAN, etc.)). These various types of communication modules may be integrated into one element (e.g., a single chip, etc.), or may be implemented as a plurality of elements (a plurality of chips) separate from each other. The wireless communication module 2292 may identify and authenticate the electronic apparatus 2201 within the communication network, such as the first network 2298 and/or the second network 2299, by using subscriber information (e.g., international mobile subscriber identity (IMSI), etc.) stored in the subscriber identity module 2296.

The antenna module 2297 may transmit a signal and/or power to the outside (e.g., another electronic apparatus, etc.) or receive a signal and/or power from the outside. An antenna may include a radiator having a conductive pattern on a substrate (e.g., a printed circuit board (PCB), etc.). The antenna module 2297 may include one or more antennas. When the antenna module 2297 includes a plurality of antennas, the communication module 2290 may select an antenna suitable for the communication scheme used in the communication network, such as the first network 2298 and/or the second network 2299, among the antennas. A signal and/or power may be transmitted or received between the communication module 2290 and another electronic apparatus through the selected antenna. In addition to the antenna, other elements (e.g., RFIC, etc.) may be included as part of the antenna module 2297.

Some elements may be connected to each other through a communication scheme between peripheral devices (e.g., bus, general purpose input and output (GPIO), serial peripheral interface (SPI), mobile industry processor interface (MIPI), etc.), and may exchange a signal (e.g., command, data, etc.) with each other.

The command or data may be transmitted or received between the electronic apparatus 2201 and the external electronic apparatus 2204 through the server 2208 connected to the second network 2299. The type of the electronic apparatuses 2202 and 2204 may be identical to or different from the type of the electronic apparatus 2201. All or part of the operations that are executed by the electronic apparatus 2201 may be executed by one or more of the electronic apparatuses 2202, 2204, and 2208. For example, when the electronic apparatus 2201 has to perform a certain function or service, the electronic apparatus 2201 may request one or more other electronic apparatuses to execute all or part of the function or service, instead of executing the function or service by itself. The one or more other electronic apparatuses receiving the request may execute an additional function or service related to the request, and may transmit a result of the executing to the electronic apparatus 2201. For this purpose, cloud computing, distributed computing, and/or client-server computing technologies may be used.

In the network environment 2200, at least the electronic apparatus 2201 may include a switching element (e.g., a transistor), and the switching element may include one of the transistors according to the embodiments described above.

The disclosed transistor may be, for example, a FET, and a protective layer (e.g., a Si layer) may be formed between a channel layer (e.g., a 2D channel) and a source/drain electrode layer in a manufacturing process. Due to the protective layer, a damage to the channel layer in the process of forming the source/drain electrode layer on the channel layer may be prevented or minimized. After the source/drain electrode layer is formed on the protective layer, heat treatment may be performed on the resulting structure. As a result, the protective layer may be transformed into a contact resistance reducing layer (e.g., a silicide layer). Therefore, because the source/drain electrode layer and the channel layer are connected to each other through the contact resistance reducing layer, the contact resistance between the source/drain electrode layer and the channel layer may be reduced.

Further, because the contact resistance between the source/drain electrode layer and the channel layer is reduced, the carrier drift velocity in the channel layer may be improved, and the amount of heat generated may be reduced, compared to a case where the contact resistance is high.

In addition, the protective layer may be formed between the channel layer and the gate insulating layer in the forming process, and the protective layer formed at this position may be a low-k dielectric layer by direct or indirect heat treatment (heat treatment in another subsequent process). The gate insulating layer may include a high-k dielectric layer. Because the low-k dielectric layer is formed between the gate insulating layer and the channel layer, remote phonon scattering may be prevented, and thus, operating characteristics of the transistor and the device including the transistor may be improved.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A field effect transistor comprising:
a substrate;
a channel layer on the substrate, the channel layer including a two-dimensional semiconductor;
a first composite electrode layer connected to a first side of the channel layer;
a second composite electrode layer connected to a second side of the channel layer;
a gate electrode layer between the first composite electrode layer and the second composite electrode layer; and
a high-k gate dielectric layer between the channel layer and the gate electrode layer,
wherein at least one of the first and second composite electrode layers comprises
a contact resistance reducing layer in contact with the channel layer, and
a conductive layer on the contact resistance reducing layer and spaced apart from the channel layer.

2. The field effect transistor of claim 1, wherein the contact resistance reducing layer comprises silicide.

3. The field effect transistor of claim 1, wherein the contact resistance reducing layer includes Ge and a metal component.

4. The field effect transistor of claim 1, further comprising:
a low-k dielectric layer between the high-k gate dielectric layer and the channel layer.

5. The field effect transistor of claim 4, wherein the contact resistance reducing layer and the low-k dielectric layer share an elemental component.

6. The field effect transistor of claim 4, wherein the low-k dielectric layer comprises an oxide layer including at least one of Si and Ge.

7. The field effect transistor of claim 1, wherein the conductive layer includes one or more types of metal.

8. The field effect transistor of claim 1, wherein the conductive layer includes at least one of Ti, Ni, Mo, W, Co, Pt, Hf, Ta, Cu, Cr, Yb, Er, or Pd.

9. The field effect transistor of claim 1, wherein the channel layer includes a semiconductor material having a band gap of 0.1 eV or more.

10. The field effect transistor of claim 1, wherein the contact resistance reducing layer includes two different types of metal and at least one of Si or Ge.

11. The field effect transistor of claim 1, further comprising:
an insulating layer protruding in a direction perpendicular to a surface of the substrate and having a first length in a direction parallel to the surface of the substrate,
wherein the insulating layer has two side surfaces and a top surface connecting the two side surfaces to each other, and
the channel layer covers the two side surfaces and the top surface of the insulating layer.

12. The field effect transistor of claim 1, wherein the channel layer comprises:
a plurality of sub-channel layers sequentially stacked in a direction perpendicular to a surface of the substrate and spaced apart from each other in the perpendicular direction, and
the gate insulating layer and the gate electrode layer surround each of the plurality of sub-channel layers.

13. The field effect transistor of claim 1, further comprising:
a plurality of insulating layers connecting the first composite electrode layer and the second composite electrode layer to each other, the plurality of insulating layers sequentially stacked in a direction perpendicular to a surface of the substrate and spaced apart from each other,
wherein the channel layer has a three-dimensional structure surrounding the plurality of insulating layers, and
the gate dielectric layer and the gate electrode layer surround each of the plurality of insulating layers on the channel layer.

14. A method of manufacturing a field effect transistor, the method comprising:
forming a channel layer on a substrate;
forming a first protective layer in contact with a first portion of the channel layer;
forming a second protective layer in contact with a second portion of the channel layer;
forming first and second conductive layers respectively in contact with the first and second protective layers and spaced apart from the channel layer;
forming first and second contact resistance reducing layers from the first and second protective layers;
forming a gate dielectric layer on the channel layer; and
forming a gate electrode layer on the gate dielectric layer.

15. The method of claim 14, further comprising:
forming a third protective layer between the channel layer and the gate dielectric layer.

16. The method of claim 15, wherein the first to third protective layers are formed simultaneously and as one protective layer.

17. The method of claim 15, wherein the third protective layer is formed before the first and second protective layers.

18. The method of claim 14, wherein the forming the first and second contact resistance reducing layers comprises heat treating the first and second conductive layers and the first and second protective layers.

19. The method of claim 15, further comprising:
forming a dielectric layer from the third protective layer such that the dielectric layer has a permittivity lower than a permittivity of the gate dielectric layer.

20. The method of claim 19, wherein the forming the dielectric layer having the permittivity lower than the permittivity of the gate dielectric layer is performed after the contact resistance reducing layer is formed.

21. The method of claim 19, wherein the forming the dielectric layer having the permittivity lower than the permittivity of the gate dielectric layer and the forming the first and second contact resistance reducing layers are performed simultaneously.

22. The method of claim 19, wherein the first and second contact resistance reducing layers and the dielectric layer having the permittivity lower than the permittivity of the gate dielectric layer include a same elemental component.

23. The method of claim 20, wherein the forming the dielectric layer having the permittivity lower than the permittivity of the gate dielectric layer comprises heat treating the third protective layer in an oxygenated environment.

24. The method of claim 14, wherein the contact resistance reducing layer includes a metal component and at least one of Si or Ge.

25. The method of claim 14, further comprising:
forming an insulating layer protruding in a direction perpendicular to a surface of the substrate and having a first length in a direction parallel to the surface of the substrate,
wherein the insulating layer has two side surfaces and a top surface connecting the two side surfaces to each other, and
the channel layer is formed to cover the two side surfaces and the top surface of the insulating layer.

26. The method of claim 14, wherein the forming of the channel layer comprises forming a plurality of sub-channel layers spaced apart from each other in a direction perpendicular to a surface of the substrate, wherein the gate dielectric layer and the gate electrode layer are formed to surround each of the plurality of sub-channel layers.

27. The method of claim 14, further comprising:
forming a plurality of insulating layers connecting a first composite electrode layer, including the first conductive layer and the first contact resistance reducing layer, and a second composite electrode layer, including the second conductive layer and the second contact resistance reducing layer, to each other, the plurality of insulating layers being spaced apart from each other in a direction perpendicular to a surface of the substrate,
wherein the channel layer is formed to surround the plurality of insulating layers, and
the gate dielectric layer and the gate electrode layer are formed to surround each of the plurality of insulating layers, on the channel layer.

28. An electronic device comprising:
a switching element; and
a data storage connected to the switching element,
wherein the switching element comprises the field effect transistor of claim 1.

29. An electronic apparatus comprising the transistor of claim 1.
